(19) United States
(12) Patent Application Publication
(10) Pub. No.: US 2025/0354061 A1
(43) Pub. Date: Nov. 20, 2025

(54) LEAD-FREE YTTERBIUM-DOPED DOUBLE PEROVSKITE THIN FILMS

(71) Applicant: New York University, New York, NY (US)

(72) Inventors: Eray Aydil, New York, NY (US); Minh Tran, Union City, NJ (US); Iver Cleveland, Brooklyn, NY (US)

(21) Appl. No.: 18/872,155

(22) PCT Filed: Jun. 6, 2023
(86) PCT No.: PCT/US2023/067966

§ 371 Date: Dec. 5, 2024

Related U.S. Application Data
(60) Provisional application No. 63/349,356, filed on Jun. 6, 2022.

(51) Int. Cl. C09K 11/74; C23C 14/06; C23C 14/24; H10K 30/40

(52) U.S. Cl. CPC C09K 11/7435; C23C 14/0694; C23C 14/24; H10K 30/40

(57) ABSTRACT

Described is a thin film comprising a Yb-doped double perovskite, wherein the double perovskite has the formula M₂AYbₓB₍₁₋ₓ₎X₆; wherein each occurrence of M independently represents Cs or Rb; A represents Ag or Cu; B represents Bi, In, Sb, or Ga; x has a value between 0.01 and 0.20; and each X independently represents F, Cl, Br, or I. Also described is a method of making the thin films. The thin film may be useful in photovoltaic devices.

### CROSS-REFERENCE TO RELATED APPLICATIONS

The present application claims priority to U.S. Provisional Application No. 63/349,356; filed Jun. 6, 2022, which is incorporated by reference herein in its entirety.

### BACKGROUND OF THE INVENTION

Redshifting the solar spectrum entering a solar cell by creating near-infrared (NIR) photons from ultraviolet (UV) and blue photons via luminescence downconversion can increase the solar cell's efficiency. Shifting the UV and blue spectrum to NIR reduces thermal losses and the recombination of electron-hole pairs generated from shallow light absorption near interfaces. Ytterbium (Yb) is a well-known luminophore for solar spectral shifting because the Yb³⁺ emission via ²F_{5/2}→²F_{7/2} electronic transition at 1.24 eV is close to the bandgap of silicon (˜1.1 eV) and copper indium gallium diselenide (CIGS) (1.0-1.2 eV) (Gloeckler, M.; Sites, J. R. Band-gap grading in Cu(In,Ga)Se₂ solar cells. J. Phys. Chem. Solids. 2005, 66, 1891-1894) Typically Yb is doped into a host, which absorbs in the UV and visible regions of the electromagnetic spectrum and transfers energy to the Yb³⁺, exciting it from the ²F_{7/2} ground state to the ²F_{5/2} state. The excited Yb³⁺ emits NIR photons at ˜1.24 eV upon relaxation. Thus, depositing a layer of a Yb-doped film with high photoluminescence quantum yield (PLQY) on top of a silicon solar cell can improve its solar cell efficiency by modifying the incident solar spectrum. Ideally, all blue (UV) photons are converted to NIR photons, and the maximum possible photoluminescence quantum yield (PLQY) is 100%.

However, there is another possibility. If the host bandgap is greater than twice the Yb³⁺ ²F_{5/2}→²F_{7/2} electronic transition, the energy transfer from the host to Yb³⁺ can be via quantum cutting, a process wherein one UV-blue photon is converted to two NIR photons. In this case, PLQY can be >100% with a maximum of 200%. Indeed, Yb-doped CsPbX₃ (X=Cl, Br) have been shown to exhibit quantum cutting with PLQY as high as 190% (Pan, G. et al. Nano Lett. 2017, 17, 8005-8011; Milstein, T, et al. Nano Lett. 2018, 18, 3792-3799; Kroupa, D. M. et al. ACS Energy Lett. 2018, 3, 2390-2395). However, lead is toxic, and NIR PLQY from CsPbX₃ decreases at high photon fluence. In the search for non-toxic alternatives to CsPbX₃, double and bismuth-based perovskites are emerging as promising hosts because they have high absorption coefficients and tunable bandgaps in the visible range (Creutz, S. E. et al., Chem. Mater. 2019, 31, 4685-4697; Creutz, S. E. et al., Nano Letters. 2018, 18 (2), 1118-1123). Specifically, Yb doping of Cs₃Bi₂Br₉, Cs₂AgInCl₆, and Cs₂AgBiBr₆ (Tran, M. N. et al. J. Mater. Chem. A, 2021,9, 13026-13035; Lee. W. et al. J. Phys. Chem. C. 2019, 123 (4), 2665-2672; Schmitz, F. et al. J. Phys. Chem. Lett. 2020, 11, 8893-8900.) has been reported. Unfortunately, 28%, the highest PLQY from Yb-doped Cs₂AgBiBr₆ thin film (Schmitz, F. et al. J. Phys. Chem. Lett. 2020, 11, 8893-8900), is still much lower than the minimum PLQY estimated to realize any increase in solar cell efficiencies (69% for typical Si solar cells and 67% for typical CIGS solar cells).

There remains a need in the art for downconverting and quantum cutting materials with high PLQY that, when placed on top of solar cells, can increase their power conversion efficiencies, and improve their lifetimes by reducing UV penetration into the solar cell and reducing solar cell heating. The present invention addresses this unmet need.

### SUMMARY OF THE INVENTION

In one aspect, the present invention relates to a thin film comprising a Yb-doped double perovskite, wherein the double perovskite has the formula M₂AYbₓB₍₁₋ₓ₎X₆; wherein each occurrence of M independently represents Cs or Rb; A represents Ag or Cu; B represents Bi, In, Sb, or Ga; x has a value between 0.01 and 0.20; and each X independently represents F, Cl, Br, or I. In one embodiment, the double perovskite has the formula M₂AYbₓB₍₁₋ₓ₎Cl_{(6-y)}Br_{y} wherein y is an integer between 0 and 6. In one embodiment, the double perovskite has the formula Cs₂AgYbₓBi₍₁₋ₓ₎Cl_{(6-y)}Br_{y}. In one embodiment, the double perovskite has the formula Cs₂AgYbₓB₍₁₋ₓ₎Br₆. In one embodiment, the value of x is between 0.05 and 0.10. In one embodiment, the value of x is between 0.06 and 0.09. In one embodiment, a photoluminescence quantum yield of the thin film is at least 45%.

In one aspect, the present invention relates to a solar cell comprising the Yb-doped double perovskite thin film. In one embodiment, the solar cell is selected from the group consisting of a silicon solar cell and a copper indium gallium selenide solar cell.

In one aspect, the present invention relates to a method of formulating a thin film, the method comprising the steps of: providing a substrate; providing a source of BX₃; providing a source of YbX₃; providing a source of AX; depositing BX₃, YbX₃, and AX on the substrate, wherein a ratio of molar flux of YbX₃ to molar flux of BX₃ is between 0.01 and 0.15; providing a source of MX; depositing MX on the substrate to provide a perovskite mixture; and annealing the mixture to provide a Yb-doped double perovskite thin film; wherein M represents Cs or Rb; A represents Ag, Cu, or Au; B represents Bi, In, Sb and Ga; and each X independently represents F, Cl, Br, or I. In one embodiment, the method further comprises the step of the step of ball milling at least one of BX₃, YbX₃, AX, and MX to produce a powder. In one embodiment, the step of depositing MX on the substrate further comprises the step of increasing the temperature of the substrate. In one embodiment, the temperature of the substrate is increased from about 30° C. to about 83° C. during the deposition of MX. In one embodiment, the ratio of molar flux of YbX₃ to BX₃ is between about 0.06 and 0.09.

In one embodiment, BX₃ represents BiX₃; AX represents AgX; MX represents CsX; and each X independently represents Br or Cl. In one embodiment, BX₃ represents BiBr₃; YbX₃ represents YbBr₃; AX represents AgBr; and MX represents CsBr. In one embodiment, the BiBr₃ is deposited at an evaporation rate of about 1.5 Å/s. The invention also relates to a thin film produced using these methods.

In one aspect, the present invention relates to a thin film comprising a Yb-doped double perovskite produced with a method comprising the steps of: providing a substrate; providing a source of BX₃; providing a source of YbX₃; providing a source of AX; depositing BX₃, YbX₃, and AX on the substrate, wherein a ratio of molar flux of YbX₃ to molar flux of BX₃ is between 0.01 and 0.15; providing a source of MX; depositing MX on the substrate to provide a perovskite mixture; and annealing the mixture to provide a Yb-doped double perovskite thin film; wherein M represents Cs or Rb; A represents Ag, Cu, or Au; B represents Bi, In, Sb and Ga; and each X independently represents F, Cl, Br, or I. In one embodiment, the ratio of molar flux of YbX₃ to BX₃ is between about 0.06 and 0.09.

### BRIEF DESCRIPTION OF THE DRAWINGS

The following detailed description of preferred embodiments of the invention will be better understood when read in conjunction with the appended drawings. For the purpose of illustrating the invention, there are shown in the drawings embodiments which are presently preferred. It should be understood, however, that the invention is not limited to the precise arrangements and instrumentalities of the embodiments shown in the drawings.

FIG. 1 is a schematic diagram of an exemplary photovoltaic device.

FIG. 2 depicts the structures of cubic CsPbBr₃ (#221, Pm 3̅ m), cubic Cs₂AgBiBr₆ (#225, Fm 3̅ m), trigonal Cs₃Bi₂Br₉ (#164, P 3̅ ml), and Ytterbium ions substituting Ag⁺ and Bi³⁺ ions in the octahedra in Cs₂AgBiBr₆.

FIG. 3 is a plot of X-ray diffraction from Yb-doped Cs₂AgBiBr₆ films and simulated powder diffraction patterns of AgBr and Cs₂AgBiBr₆ for comparison. All data and images are from films annealed at 300° C. for one hour.

FIG. 4 is a plot of X-ray diffraction (XRD) patterns as-deposited Yb-doped Cs₂AgBiBr₆ films. XRD of films doped with 5-14% Yb show multiple weak peaks that do not belong to Cs₂AgBiBr₆. Simulated (using VESTA software) XRD patterns of AgBr, Cs₂AgBiBr₆, and Cs₃Bi₂Br₉ using CIF files are shown for comparison.

FIG. 5 is a plot of Raman spectra of as-deposited Yb-doped Cs₂AgBiBr₆ films. Films doped with 5-14% Yb have Raman peaks at 197 and 170 cm⁻¹, which belong to an impurity phase, Cs₃Bi₂Br₉. This impurity phase peaks match with the XRD of Cs₃Bi₂Br₉.

FIG. 6 depicts Scanning electron micrographs (SEMs) of Yb-doped (10% Yb) Cs₂AgBiBr₆ films annealed in a nitrogen-filled glove box under different conditions showing the effects of annealing temperature and annealing duration. The average composition of the larger crystal domains (e.g., large irregular domains in the first image and elongated crystals in the second and third images is 57.2% Br, 16.9% Ag, 21.4% Cs, 0.3% Yb, and 4.2% Bi, suggesting that the impurity is a Cs—Ag—Br phase, possibly CsAgBr₂ (#63, Cmcm). The small Bi signal detected is likely coming from the Cs₂AgBiBr₆ surrounding or beneath these regions.

FIG. 7 is a plot of Raman scattering of Cs₂AgBiBr₆ as-deposited films and films annealed at different temperatures. When annealed at 350° C., Cs₂AgBiBr₆ decomposes, possibly to Cs₃BiBr₆, as shown in the Raman spectra.

FIG. 8 is a plot of XRD from Cs₂AgBiBr₆ as-deposited films and films annealed at different temperatures.

FIG. 9 depicts SEM images of Cs₂AgBiBr₆ films annealed at different temperatures for 1 hour: as-deposited, 250° C.; 300° C., and 350° C. Films decompose when annealed at 350° C.

FIG. 10 depicts Raman spectra of undoped and Yb-doped Cs₂AgBiBr₆ films. All data and images are from films annealed at 300° C. for one hour.

FIG. 11 is a series of representative SEM images of Yb-doped (8%) Cs₂AgBiBr₆ films at different magnifications. All data and images are from films annealed at 300° C. for one hour.

FIG. 12 is a series of SEM images Cs₂AgBiBr₆ films doped with 0-14% Yb annealed at 300° C. for 1 hour: 0% Yb, 3% Yb, 5% Yb, 8% Yb, 10% Yb, and 14% Yb.

FIG. 13 depicts the absorbance and photoluminescence of Cs₂AgBiBr₆ thin film annealed at 300° C. for 1 hour. The inset is the PL from an as-deposited Cs₂AgBiBr₆ thin film.

FIG. 14 depicts XRD patterns from Cs₂AgBiCl_{y}Br_{6-y} thin films, and simulated XRD patterns of Cs₂AgBiCl₆ and Cs₂AgBiBr₆. As dotted lines show, XRD peaks are shifted to higher 2θ values with increasing amounts of chlorine, suggesting that two halide ions are mixed throughout the films. XRD Cs₂AgBiBr₂Cl₄ contains impurity peaks of Cs₂AgBiCl₆, suggesting phase segregation in this film after annealing.

FIG. 15 is a plot of normalized absorbance from Cs₂AgBiCl_{y}Br_{6-y} thin films thin film annealed at 300° C. for 1 hour. Thin-film interference fringes and background due to scattering were subtracted from the absorption spectra.

FIG. 16 is a plot of normalized photoluminescence from Cs₂AgBiCl_{y}Br_{6-y} thin films thin film annealed at 300° C. for 1 hour. Thin-film interference fringes and background due to scattering were subtracted from the absorption spectra.

FIG. 17 is a plot demonstrating that visible photoluminescence from Cs₂AgBiBr₆ thin film decreases after the film is annealed at 300° C. for one hour.

FIG. 18 is a depiction of energy transfer processes in Yb-doped Cs₂AgBiBr₆.

FIG. 19 is a plot of absorption and excitation (λₑₘ=997 nm) spectra of Cs₂AgBiBr₆ thin film doped with 8% Yb and annealed at 300° C. for 1 hour. NIR PLQY at different excitation wavelengths is also plotted.

FIG. 20 is a plot of orange and NIR PL from Cs₂AgBiBr₆ thin film doped with 8% Yb and annealed at 300° C. for 1 hour.

FIG. 21 is a plot of the orange emission from Cs₂AgBiBr₆ thin films doped with 3-14% Yb. Emissions at all Yb levels are weak, as the noise suggests. However, the orange emission from 10% Yb—Cs₂AgBiBr₆ film was particularly weak, and it is difficult to distinguish between the film's PL and stray light, so its PL is not included here.

FIG. 22 is a plot showing the dependence NIR PLQY of Cs₂AgBiBr₆ films doped with 3-14% Yb annealed under different conditions.

FIG. 23 is a plot of the PLQY of Cs₂AgBiBr₆ films doped with 3 to 14% Yb and annealed at 300° C. for one hour. PL intensity of each film is scaled with PLQY.

FIG. 24 depicts the long term stability of the PLQY of Cs₂AgBiBr₆ films doped with 8% Yb and annealed at 300° C. for one hour. The intensity is scaled with the corresponding quantum yield. PL was excited at 420 nm (10 nm bandwidth).

FIG. 25 is a plot showing how external quantum efficiency of a typical CIGS solar cell changes after a layer of down-conversion materials is deposited on top of the solar cell. (Friedlmeier, T. M. et al., IEEE 42^{nd} Photovoltaic Specialist Conference. 2015, 1-3) For example, with 82.5% of PLQY, the solar cell's efficiency can increase from 20.4 to 20.7% for CIGS.

FIG. 26 is a plot showing how the external quantum efficiency of a typical silicon solar cell (Mazzarella, L. et al., Appl. Phys. Lett. 2015, 106, 023902) changes after a layer of down-conversion materials is deposited on top of the solar cell. For example, with 82.5% of PLQY, the solar cell's efficiency can increase from 20.3 to 20.6% for Si.

FIG. 27 shows how Ytterbium ions substitute Bi³⁺ ions and Ag⁺ ions in the octahedra in Cs₂AgBiBr₆ (#225, Fm3̅m). The alternating colors depict the alternating [AgBr₆]⁵⁻ and [BiBr₆]³⁻ octahedra.

FIG. 28 is a plot of NIR emission spectrum of a 8% Yb-doped Cs₂AgBiBr₆ thin film.

FIG. 29 is a plot of temperature profiles during depositions and the corresponding photoluminescence quantum yield of the 8% Yb-doped Cs₂AgBiBr₆ thin films synthesized under each temperature condition.

FIG. 30 depicts the XRD of as-deposited films before annealing without substrate temperature control (no temp control), with substrate temperature controlled at 30° C. and 48° C. and substrate temperature ramped to 70° C. during CsBr deposition. Simulated XRD patterns of the target product, Cs₂AgBiBr₆, the precursor, AgBr, a possible intermediate, CsAgBr₂, and a common bismuth perovskite phase, Cs₃Bi₂Br₉ are shown for comparison. The dashed lines mark the diffraction peaks of CsAgBr₂ and AgBr, both of which are present in the as-deposited films regardless of the deposition temperature or the temperature control mode.

FIG. 31 depicts X-ray diffraction patterns (shifted for clarity) of 8% Yb-doped Cs₂AgBiBr₆ thin films deposited at different substrate temperatures (Tₛ) and the simulated reference pattern of Cs₂AgBiBr₆.

FIG. 32 depicts XRD pattern of Cs₂AgBiBr₆ films doped with 8% Yb deposited at 75° C. Calculated XRD patterns for Cs₂AgBiBr₆ and Cs₃BiBr₆ are shown for reference.

FIG. 33 depicts SEM images of Cs₂AgBiBr₆ films doped with 8% Yb deposited at 75° C. Impurity phases appear as rod-like morphologies. The EDS composition of these phases is 7.4% Bi, 20.6% Cs, 65.1% Br, 5.8% Ag, and 1.1% Yb. The ratio Cs:Bi:Br is 2.8:1.0:8.8, close to that expected in Cs₃BiBr₆.

FIG. 34 depicts SEM images of Cs₂AgBiBr₆ films doped with 8% Yb deposited in: no-temperature-control mode, constant-temperature mode at 30° C., constant-temperature mode at 48° C., constant-temperature mode at 75° C., ramping-temperature mode to 70° C. and ramping-temperature mode to 83° C. All films were annealed at 300° C.

FIG. 35 depicts PLQY of 8% Yb-doped Cs₂AgBiBr₆ films deposited under the ramping condition to 83° C. with varying BiBr₃ evaporation rates. PLQYs are average values of multiple films synthesized under the same conditions.

FIG. 36 depicts initial PLQY of 8% Yb-doped Cs₂AgBiBr₆ films deposited under the ramping condition to 83° C. with varying BiBr₃ evaporation rates and after exposed to air for a few days. PLQYs are not average values and come from one set of films.

FIG. 37 depicts XRD of 8% Yb-doped Cs₂AgBiBr₆ films deposited under the ramping condition to 83° C. with varying BiBr₃ evaporation rates.

FIG. 38 is a plot of PLQY stability of a Cs₂AgBiBr₆ film doped with 8% Yb after removal from the glove box and exposure to air. The Cs₂AgBiBr₆ film was deposited in the ramping-temperature mode as the substrate temperature was increased from 30° C. to 83° C. during CsBr evaporation. The BiBr₃ evaporation rate was 1.5 Å/s. Day 0 is when the film was deposited, annealed, and removed from the glovebox.

FIG. 39 depicts the excitation spectrum of 8% Yb-doped Cs₂AgBiBr₆ thin film synthesized with the BiBr₃ evaporation rate of 1.5 Å/s and the ramping temperature to 83° C. PLQY corresponding to each excitation wavelength is included. PLQY measurements in this graph are measured after the film is exposed to air for 1 month.

FIG. 40 depicts absorption and excitation spectra of 8% Yb-doped Cs₂AgBiBr₆ thin film synthesized with the BiBr₃ evaporation rate of 1.5 Å/s and the ramping temperature to 83° C.

FIG. 41 depicts SEM images of Cs₂AgBiBr₆ films doped with 8% Yb deposited using the temperature-ramping mode, where the substrate temperature was increased from 30° C. to 83° C. The different images correspond to films deposited using varying BiBr₃ evaporation rates. All films were annealed at 300° C. for one hour.

FIG. 42 depicts XRD of 8% Yb-doped Cs₂AgBiCl₄Br₂ films deposited with stoichiometric or 50% excess BiCl₃. Films are co-deposited or sequentially deposited, and the substrate temperature is ramped as described in the text during the depositions. XRD reference patterns of Cs₂AgBiCl₆ and Cs₂AgBiBr₆ are included for comparison. NIR PLQY values of the films are also shown. XRDs are offset for clarity.

FIG. 43 depicts SEM images of 8% Yb-doped Cs₂AgBiCl₄Br₂ films deposited with stoichiometric ratio and 50% excess BiCl₃ fluxes. Films are co- or sequentially deposited, and the substrate temperature is ramped during the deposition as described in the text. Some SEMs show crystallites that appear different than the background films and are presumed to be impurity phases. Compositions of the impurity phases, measured using EDS, vary and differ from the homogeneous background film. The EDS shows the presence of Bi-deficient phases in small volume fractions not detectable using XRD. For example, the triangular crystal in FIG. 43d comprises 20.8% Cs, 17.3% Ag, 7.6% Bi, 34.8% Cl, 18.8% Br, and 0.6% Yb: Bi concentration is lower than that expected in stoichiometric Cs₂AgBiCl₄Br₂ (20% Cs, 10% Ag, 10% Bi, 40% Cl, and 20% Br).

FIG. 44 depicts XRD patterns of Yb-doped Cs₂AgBiCl₄Br₂ films sequentially deposited with 50% excess BiCl₃ and different concentrations of Yb from 3 to 20%. NIR PLQY for each film is also included.

FIG. 45 depicts SEM images of Yb-doped Cs₂AgBiCl₄Br₂ films sequentially deposited with 50% excess BiCl₃ and different concentrations of Yb from 3 to 20%.

FIG. 46 depicts XRD patterns and Raman spectra of Yb-doped Cs₂AgBiBr₆ powders and after annealing. The reference patterns of Cs₂AgBiBr₆ is also included for comparison.

FIG. 47 depicts the near-infrared emission curve of Yb-doped Cs₂AgBiBr₆ annealed powders with PLQY of 51%.

FIG. 48 depicts XRD patterns and Raman spectra of Yb-doped Cs₂AgBiBr₆ as-deposited and annealed films. The reference XRD pattern of Cs₂AgBiBr₆ and AgBr are included. The reference Raman pattern of Cs₂AgBiBr₆ and Cs₃Bi₂Br₉ are also included.

FIG. 49 depicts the near-infrared emission curve of Yb-doped Cs₂AgBiBr₆ annealed film.

### DETAILED DESCRIPTION

It is to be understood that the Figures and descriptions of the present invention have been simplified to illustrate elements that are relevant for a clear understanding of the present invention, while eliminating, for the purpose of clarity, many other elements found in photovoltaic devices. Those of ordinary skill in the art may recognize that other elements and/or steps are desirable and/or required in implementing the present invention. However, because such elements and steps are well known in the art and because they do not facilitate a better understanding of the present invention, a discussion of such elements and steps is not provided herein. The disclosure herein is directed to all such variations and modifications to such elements and methods known to those skilled in the art.

As used herein, each of the following terms has the meaning associated with it in this section. Unless defined otherwise, all technical and scientific terms used herein generally have the same meaning as commonly understood by one of ordinary skill in the art to which this invention belongs.

The articles “a” and “an” are used herein to refer to one or to more than one (i.e. to at least one) of the grammatical object of the article. By way of example, “an element” means one element or more than one element.

As used herein, the term “about” will be understood by persons of ordinary skill in the art and will vary to some extent depending on the context in which it is used. As used herein when referring to a measurable value such as an amount, a temporal duration, and the like, the term “about” is meant to encompass variations of ±20% or ±10%, more preferably ±5%, even more preferably ±1%, and still more preferably ±0.1% from the specified value, as such variations are appropriate to perform the disclosed methods.

As used herein, the term “substrate” refers to a structural surface beneath a layered material or coating (e.g., deposited material).

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

### DESCRIPTION

The present invention is based in part on the unexpected discovery that Yb-doped double perovskite films can be used a down-converting coating on solar cells.

### Methods of Formulating a Thin Film

In one aspect, the present invention relates to a method of formulating a Yb-doped double perovskite thin film, the method comprising the steps of providing a substrate; providing a source of BX₃, providing a source of YbX₃; providing a source of AX; depositing BX₃, YbX₃, and AX on the substrate, wherein a ratio of molar flux of YbX₃ to molar flux of BX₃ is between 0.01 and 0.15; providing a source of MX; depositing MX on the substrate to provide a perovskite mixture, and annealing the mixture to provide a Yb-doped double perovskite thin film; wherein M represents Cs or Rb; A represents Ag, Cu, or Au; B represents Bi, In, Sb and Ga; and each X independently represents F, Cl, Br, or I.

In one embodiment, B represents Bi. In one embodiment, M represents Cs. In one embodiment, A represents Ag. In one embodiment, each X represents Cl or Br.

In one embodiment, the rate of deposition of the various components can be tuned, which may affect resulting photoluminescence characteristics. In one embodiment, the temperature of the substrate and/or the temperature of the deposition apparatus may be tuned, which may affect the resulting photoluminescence characteristics. In one embodiment, the BX₃ is deposited at a rate between 1.0 Å/s and 2.0 Å/s. In one embodiment, the BX₃ is deposited at a rate between 1.0 Å/s and 1.8 Å/s. In one embodiment, BX₃ is deposited at a rate of about 1.5 Å/s. In one embodiment, BX₃ represents BiBr₃.

In one embodiment, the method comprises the steps of providing a substrate, depositing BiBr₃, YbBr₃, and AgBr on the substrate; depositing CsBr on the substrate; and annealing the thin film.

As contemplated herein, the percent doping of Yb in the double perovskite is meant to indicate the ratio of the molar flux of the Yb-containing precursor YbX₃ to that of the BX₃ precursor. Thus, in one embodiment, Yb can be varied between 0% and 14% by controlling the YbBr₃ evaporation rate. For example, in some embodiments, to deposit a 3% Yb-doped Cs₂AgBiBr₆, the ratio of YbBr₃ molar flux to BiBr₃ molar flux is set to 0.03. In one embodiment, the ratio of YbBr₃ molar flux to BiBr₃ molar flux is between 0.01 and 0.10. In one embodiment, the ratio of YbBr₃ molar flux to BiBr₃ molar flux is between 0.05 and 0.10. In one embodiment, the ratio of YbBr₃ molar flux to BiBr₃ molar flux is between 0.06 and 0.09. In one embodiment, the ratio of YbBr₃ molar flux to BiBr₃ molar flux is between 0.075 and 0.085. In one embodiment, the ratio of YbBr₃ molar flux to BiBr₃ molar flux is about 0.010. In one embodiment, the ratio of YbBr₃ molar flux to BiBr₃ molar flux is about 0.015. In one embodiment, the ratio of YbBr₃ molar flux to BiBr₃ molar flux is about 0.020. In one embodiment, the ratio of YbBr₃ molar flux to BiBr₃ molar flux is about 0.025. In one embodiment, the ratio of YbBr₃ molar flux to BiBr₃ molar flux is about 0.030. In one embodiment, the ratio of YbBr₃ molar flux to BiBr₃ molar flux is about 0.035. In one embodiment, the ratio of YbBr₃ molar flux to BiBr₃ molar flux is about 0.040. In one embodiment, the ratio of YbBr₃ molar flux to BiBr₃ molar flux is about 0.045. In one embodiment, the ratio of YbBr₃ molar flux to BiBr₃ molar flux is about 0.050. In one embodiment, the ratio of YbBr₃ molar flux to BiBr₃ molar flux is about 0.055. In one embodiment, the ratio of YbBr₃ molar flux to BiBr₃ molar flux is about 0.060. In one embodiment, the ratio of YbBr₃ molar flux to BiBr₃ molar flux is about 0.065. In one embodiment, the ratio of YbBr₃ molar flux to BiBr₃ molar flux is about 0.070. In one embodiment, the ratio of YbBr₃ molar flux to BiBr₃ molar flux is about 0.075. In one embodiment, the ratio of YbBr₃ molar flux to BiBr₃ molar flux is about 0.080. In one embodiment, the ratio of YbBr₃ molar flux to BiBr₃ molar flux is about 0.085. In one embodiment, the ratio of YbBr₃ molar flux to BiBr₃ molar flux is about 0.090. In one embodiment, the ratio of YbBr₃ molar flux to BiBr₃ molar flux is about 0.095. In one embodiment, the ratio of YbBr₃ molar flux to BiBr₃ molar flux is about 0.100.

In one embodiment, the BX₃, YbX₃, and AX are deposited simultaneously. In one embodiment, the step of depositing BX₃, YbX₃, and AgX comprises the step of evaporating sources BX₃, YbX₃, and AX in the presence of a substrate, wherein the temperature of the substrate is lower than the temperature of the sources of BX₃, YbX₃, and AX.

In one embodiment, the temperature of the substrate is constant throughout the deposition process. In one embodiment, the temperature of the substrate increases throughout the deposition process. In one embodiment, the step of depositing MX on the substrate further comprises the step of increasing the temperature of the substrate. In one embodiment, the temperature of the substrate is increased from about 30° C. to about 83° C. over the course of the MX deposition.

In one embodiment, one or more of the precursors BX₃, YbX₃, AX, and MX are pre-milled to a homogenous powder prior to deposition. In one embodiment, the milling step reduces particle size and affords more efficient physical vapor deposition. Equipment that may be used for precursor milling includes but not limited to a ball mill, a roller mill, a hammer mill, and a jet mill.

In one embodiment, one or more of the precursors are pre-milled in a ball mill. Ball mills are used in the present invention to obtain a homogenous powder. In one embodiment, the ball mill comprises a fixed cylindrical vessel such as those known to the person of ordinary skill in the art. The axis of the cylinder can be both horizontal and have a small angle with the horizontal. In one embodiment, the ball mill is partially filled with balls. Abrasive media are made of ceramic or zirconia (beads between 3 mm to 10 mm). The inner surface of the cylinder is normally crossed out with an abrasion resistant material such as manganese steel. The ball mill rotates around a horizontal axis, partially filled with the material to be ground plus the abrasive medium, an internal cascade effect reduces the material to a fine powder.

In one embodiment, the centrifugal force in the ball mill is extremely high, resulting in very short grinding times. Ball mills have the advantage of powerful and fast crushing down to the submicron range, in addition the energy and speed are adjustable so that reproducible results are guaranteed. In one embodiment, the precursors are dry-milled. In one embodiment, the precursors are wet-milled (i.e., milled in the presence of water). In one embodiment, the precursors are milled in the presence of a suitable solvent for the desired powder properties.

### Thin Films

In one aspect, the present invention relates in part to thin films comprising a double perovskite and at least one dopant, wherein the at least one dopant comprises Yb; and wherein the double perovskite has the formula M₂AYbₓB₍₁₋ₓ₎X₆; wherein each M independently Cs or Rb; A represents a monovalent ion such as Ag, Cu, or Au; B represents a trivalent ion such as Bi, In, Sb and Ga; x has a value between 0.01 and 0.20; and each X independently represents F, Cl, Br, or I. In one embodiment, neither the double perovskite nor the dopant comprises lead.

In one embodiment, the double perovskite has the formula M₂AYbₓB₍₁₋ₓ₎Cl_{(6-y)}Br_{y} wherein y is a number between 0 and 6. In one embodiment, the double perovskite has the formula Cs₂AgYbₓBi₍₁₋ₓ₎Cl_{(6-y)}Br_{y}. In one embodiment, the double perovskite has the formula Cs₂AgYbₓBi₍₁₋ₓ₎Br₆. In one embodiment, the double perovskite has the formula Cs₂AgBiCl₆. In one embodiment, the double perovskite has the formula Cs₂AgYbₓBi₍₁₋ₓ₎Br₆. In one embodiment, the double perovskite has the formula Cs₂AgYbₓB₍₁₋ₓ₎Cl₄Br₂.

In one embodiment, the thin film red-shifts incident UV and blue radiation to near-infrared radiation. In one embodiment, the photoluminescence quantum yield of the thin film is at least 45%.

In one embodiment, the Yb atoms in the double perovskite replace positions held by B atoms, such as Bi atoms. Thus, the Yb content is reported in percent of the B lattice positions displaced in the M₂ABX₆ structure, or M₂AYbₓB₍₁₋ₓ₎X₆. In one embodiment, x has a value between 0.01 and 0.15. In one embodiment, x has a value between 0.01 and 0.10. In one embodiment, x has a value between 0.05 and 0.10. In one embodiment, x has a value between 0.06 and 0.09. In one embodiment, x has a value of about 0.010. In one embodiment, x has a value of about 0.015. In one embodiment, x has a value of about 0.020. In one embodiment, x has a value of about 0.025. In one embodiment, x has a value of about 0.030. In one embodiment, x has a value of about 0.035. In one embodiment, x has a value of about 0.040. In one embodiment, x has a value of about 0.045. In one embodiment, x has a value of about 0.050. In one embodiment, x has a value of about 0.055. In one embodiment, x has a value of about 0.060. In one embodiment, x has a value of about 0.065. In one embodiment, x has a value of about 0.070. In one embodiment, x has a value of about 0.075. In one embodiment, x has a value of about 0.080. In one embodiment, x has a value of about 0.085. In one embodiment, x has a value of about 0.090. In one embodiment, x has a value of about 0.095. In one embodiment, x has a value of about 0.100.

In another aspect, the present invention relates to a thin film composition comprising a Yb-doped double perovskite, wherein the double perovskite has the formula M₂ABX₆; wherein each M independently Cs or Rb; A represents a monovalent ion such as Ag, Cu, or Au; B represents a trivalent ion such as Bi, In, Sb and Ga; and each X independently represents F, Cl, Br, or I; and wherein the composition further comprises a 1% to 15% of a Yb dopant. As contemplated herein, the percent doping of Yb (or, the Yb content) in the double perovskite is meant to indicate the ratio of the molar flux of the Yb-containing precursor YbX₃ to that of the BX₃ precursor during the synthesis of the thin film composition. Thus, in one embodiment, Yb can be varied between 0% and 15% by controlling the YbBr₃ evaporation rate. For example, in some embodiments, to deposit a 3% Yb-doped Cs₂AgBiBr₆, the ratio of YbBr₃ molar flux to BiBr₃ molar flux is set to 0.03. In one embodiment, the Yb content is between 5% and 10%. In one embodiment, the Yb content is about 8%. In one embodiment, neither the double perovskite nor the dopant comprises lead.

In one embodiment, the double perovskite has the formula M₂ABCl_{(6-y)}Br_{y} wherein y is a number between 0 and 6. In one embodiment, the double perovskite has the formula Cs₂AgBiCl_{(6-y)}Br_{y}. In one embodiment, the double perovskite has the formula Cs₂AgBiBr₆. In one embodiment, the double perovskite has the formula Cs₂AgBiCl₆. In one embodiment, the double perovskite has the formula Cs₂AgBiCl₂Br₄. In one embodiment, the double perovskite has the formula Cs₂AgBiCl₄Br₂.

In one aspect, the present invention relates to a solar cell comprising a thin film disclosed herein. In a solar cell, the active layer converts photons (incident light) to excitons, which comprise an electron and a hole. The potential between the electrodes drives the electrons to the cathode and the holes to the anode, thereby generating an electric current. In one embodiment, the solar cell is a silicon solar cell. In one embodiment, the solar cell is a copper indium gallium selenide (CIGS) solar cell.

### Photovoltaic Devices

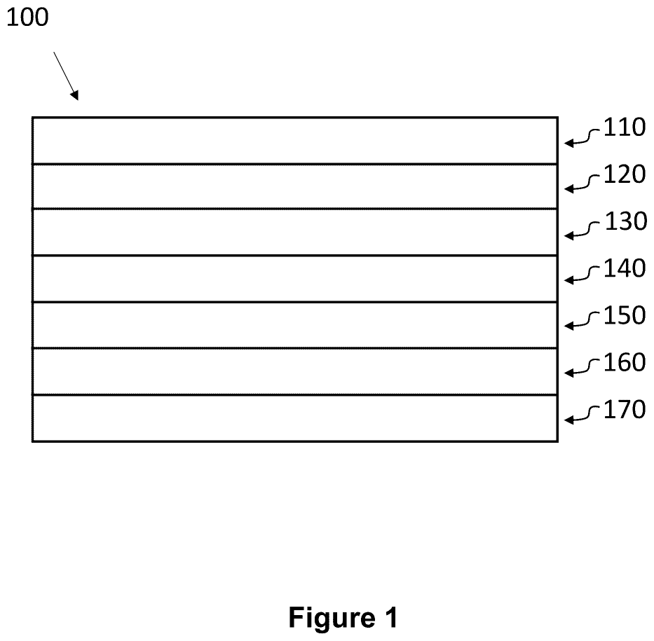

The present invention relates in part to photovoltaic devices comprising a thin film of the present invention. Referring to FIG. 1, exemplary photovoltaic device 100 is shown. In some embodiments, device 100 may include: down-converting thin film 110, first electrode 120, optional charge transporting layer 130, active layer 140, optional charge transporting layer 150, second electrode 160, and optional substrate 170. In some embodiments, the device may be encapsulated with glass from the top and the bottom, and the down-converting thin film 110 may be formed on the front or back of the top glass cover.

In some embodiments, first electrode 120 is a cathode, transporting layer 130 is an electron transporting layer, transporting layer 150 is a hole transporting layer, and second electrode 160 is an anode. In other embodiments, first electrode 120 is an anode, transporting layer 130 is a hole transporting layer, transporting layer 150 is an electron transporting layer, and second electrode 160 is a cathode.

First electrode 120 and second electrode 160 may comprise any material capable of conducting electrons. In one embodiment, the cathode is a low work function metal or metal alloy, including, for example, barium, calcium, magnesium, indium, aluminum, ytterbium, silver, a calcium:silver alloy, an aluminum:lithium alloy, or a magnesium:silver alloy. In some embodiments, first electrode 120 and second electrode 160 comprise gold, silver, fluorine tin oxide (FTO) or indium tin oxide (ITO), or conductive polymer layers. In some embodiments, either of first electrode 120 and second electrode 160, or both of first electrode 120 and second electrode 160, are reflective, transparent, semi-transparent or translucent.

In some embodiments, optional charge transporting layers 130 and 150 are independently an electron transporting layer and a hole transporting layer. In one embodiment, the electron transporting layer comprises a material capable of transporting electrons. In some embodiments, the hole transporting layer, when present, is in direct contact with the anode. In some embodiments, the electron transporting material, when present, is in direct contact with the cathode.

Exemplary electron transporting materials include, but are not limited to, semi-conductive metal oxides including oxides of titanium, tin, zinc, iron, tungsten, zirconium, hafnium, strontium, indium, cerium, yttrium, lanthanum, vanadium, caesium, niobium or tantalum, metal chelated oxinoid compounds, such as bis(2-methyl-8-quinolinolato)(para-phenyl-phenolato)aluminum(II) (BAlQ), tris(8-hydroxyquinolato)aluminum (Alq₃), and tetrakis(8-hydroxyquinolato)-aluminum (ZrQ); azole compounds such as 2-(4-biphenylyl)-5-(4-t-butylphenyl)-1,3,4-oxadiazole (PB D), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; and phenanthroline derivatives such as 9,10-diphenylphenanthroline (DPA) and 2,9-dimethyl-4,7-diphenyl-1,10-phenanthroline (DDPA). In one embodiment, the electron transporting layer comprises TiO₂, SnO₂, Fe₂O₃, WO₃, ZnO, Nb₂O₅, SrTiO₃, Ta₂O₅, Cs₂O, zinc stannate, complex oxides such as barium titanate, binary and ternary iron oxides, or indium gallium zinc oxide (IGZO).

There is no particular limit to the composition of active layer 140. In one embodiment, the active layer comprises silicon. In one embodiment, the active layer comprises copper indium gallium selenide. In some embodiments, the active layer may include a stack of sublayers arranged for the purpose of absorbing different regions of the solar spectrum. In some embodiments, the active layer may include a stack of sublayers with different doping levels for promoting the separation of electrons and holes.

In certain embodiments, electrode 160 may be deposited on a substrate 170, which may be transparent, semi-transparent, translucent, or opaque. Substrate 170 may be rigid, for example quartz or glass, or may be a flexible polymeric substrate. Examples of flexible transparent semi-transparent or translucent substrates include, but are not limited to, polyimides, polytetrafluoroethylenes, polyethylene terephthalates, polyolefins such as polypropylene and polyethylene, polyamides, polyacrylonitrile and polyacrionitrile, polymethacrylonitrile, polystyrenes, polyvinyl chloride, and fluorinated polymers such as polytetrafluoroethylene.

### EXPERIMENTAL EXAMPLES

The invention is now described with reference to the following Examples. These Examples are provided for the purpose of illustration only, and the invention is not limited to these Examples, but rather encompasses all variations that are evident as a result of the teachings provided herein.

### Example 1: High Photoluminescence Quantum Yield Near-Infrared Emission from a Lead-Free Ytterbium-Doped Double Perovskite

Yb-doped Cs₂AgBiBr₆ is a promising downconversion materials to redshift UV and blue photons to near-infrared. Cs₂AgBiBr₆ has a stable cubic structure at room temperature (#225, Fm3̅m, a=11.2499 Å) (Gloeckler, M. Sites, J. R. J. Phys. Chem. Solids. 2005, 66, 1891-1894), and an indirect bandgap of ˜2.2 eV. When excited with photons with energies greater than 2.2 eV, the bandgap energy, Yb-doped Cs₂AgBiBr₆ thin films synthesized via physical vapor deposition emit strong near-infrared luminescence centered at ˜1.24 eV via the Yb^{3+ 2}F_{5/2}→²F_{7/2} electronic transition. Robust, reproducible, and stable photoluminescence quantum yields (PLQY) as high as 82.5% are achieved with Cs₂AgBiBr₆ films doped with 8% Yb. Furthermore, PLQY remains high (>94% of initial value) after two months without encapsulation. This high PLQY indicates facile and efficient energy transfer from the perovskite host, Cs₂AgBiBr₆, to Yb, making Cs₂AgBiBr₆ the most promising lead-free downconversion material for solar spectrum shifting to increase solar cell efficiencies.

Herein, Yb-doped Cs₂AgBiBr₆ films with a maximum NIR PLQY of 82.5% and PLQY consistently in the 71-82.5% range for excitation energies above the bandgap (>2.2 eV) are disclosed, the highest values to date from a Yb-doped lead-free perovskite.

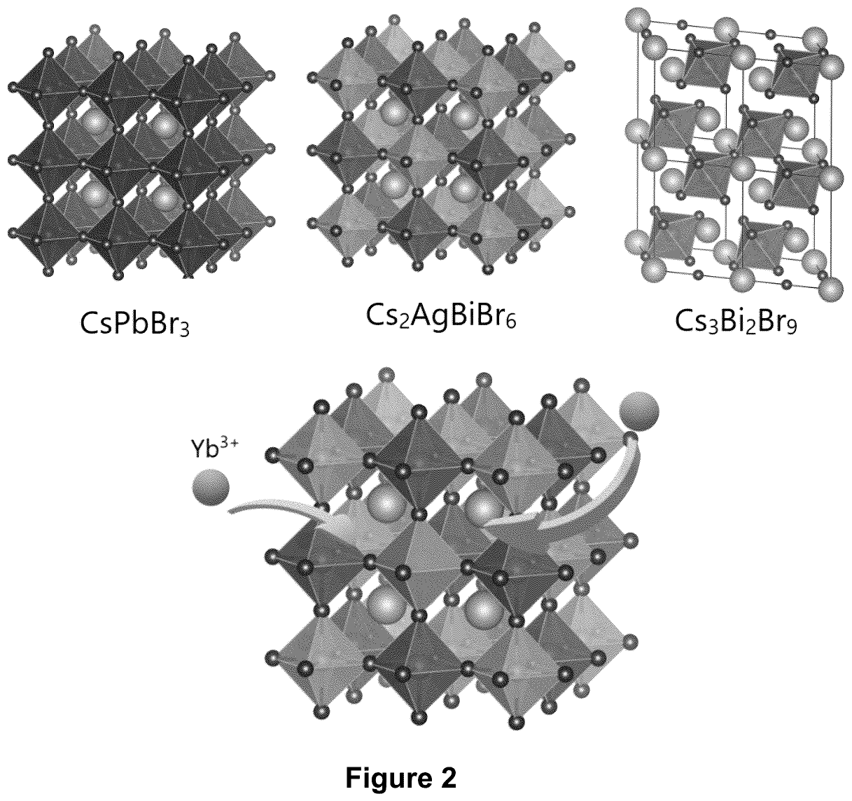

The double perovskite, Cs₂AgBiBr₆, crystallizes in a stable cubic structure (#225, Fm3̅m, a=11.2499 Å,) at room temperature. The structure can be viewed as a derivative of the widely studied CsPbBr₃, wherein the Pb²⁺ in alternating [PBr₆]⁴⁻ octahedra are replaced by Ag⁺ or Bi³⁺, forming a 3D network of corner-sharing [AgBr₆]⁵⁻ and [BiBr₆]³⁻ octahedra which alternate periodically (FIG. 2). When CsPbX₃ is doped with Yb, Yb³⁺ is thought to substitute Pb²⁺ ions in the octahedra. Yb³⁺ can replace Bi³⁺ and Ag⁺ ions when doped in Cs₂AgBiBr₆, as shown in FIG. 2. Yb³⁺ substituting isovalent Bi³⁺ would not need to create a vacancy or an antisite defect, whereas substituting Ag⁺ has to be accompanied by charge compensating defects such as Ag vacancies (V_{Ag}) or Ag antisite (Ag_{Bi}) defects.

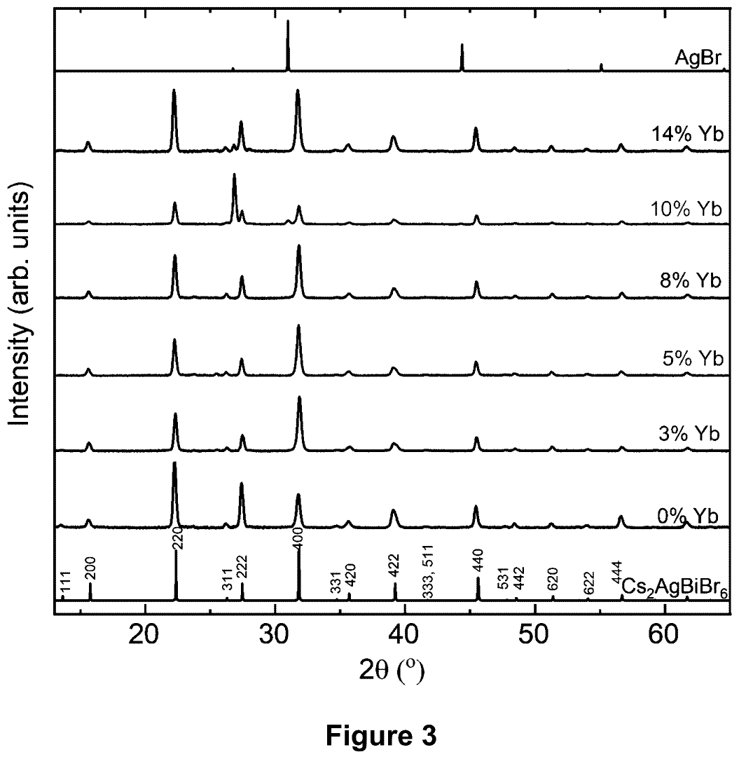

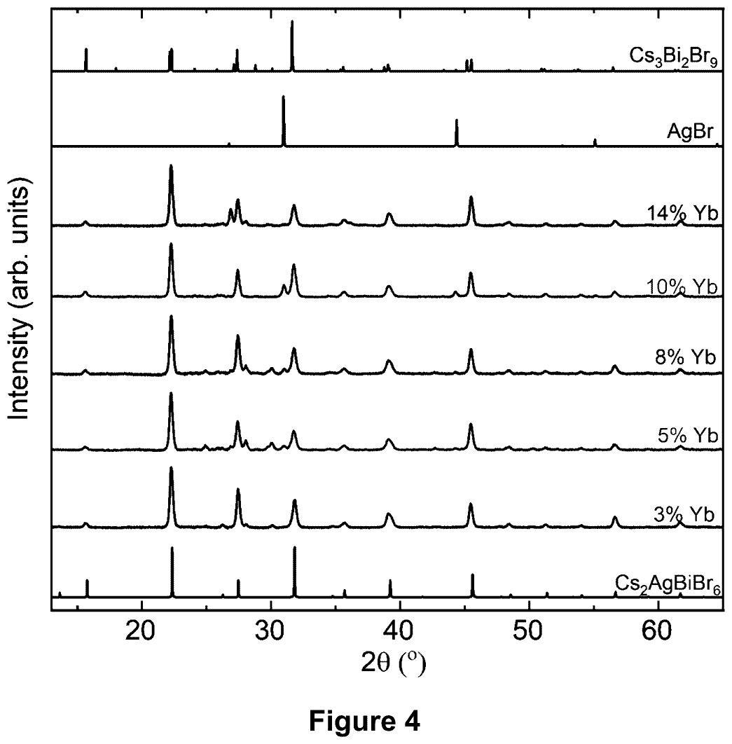

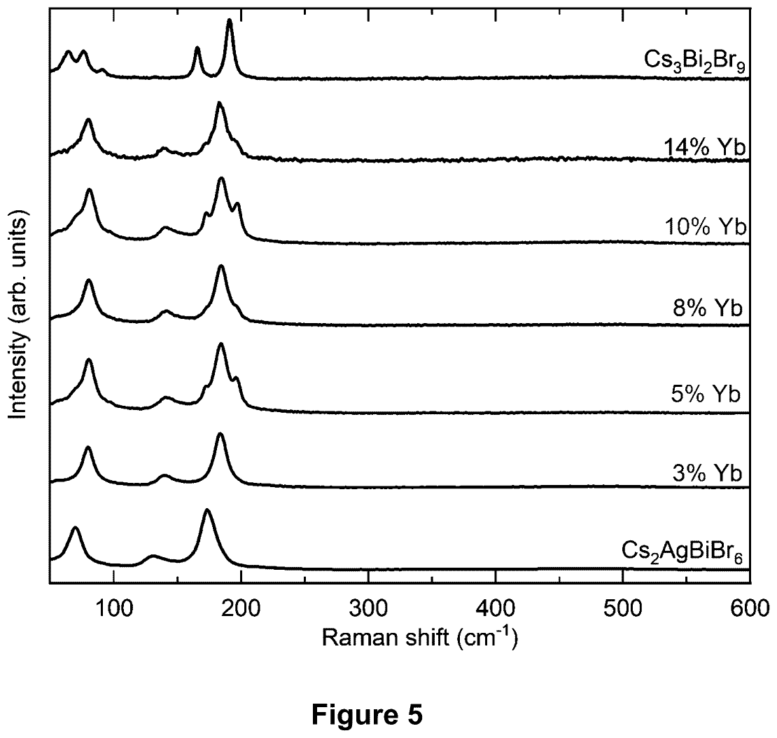

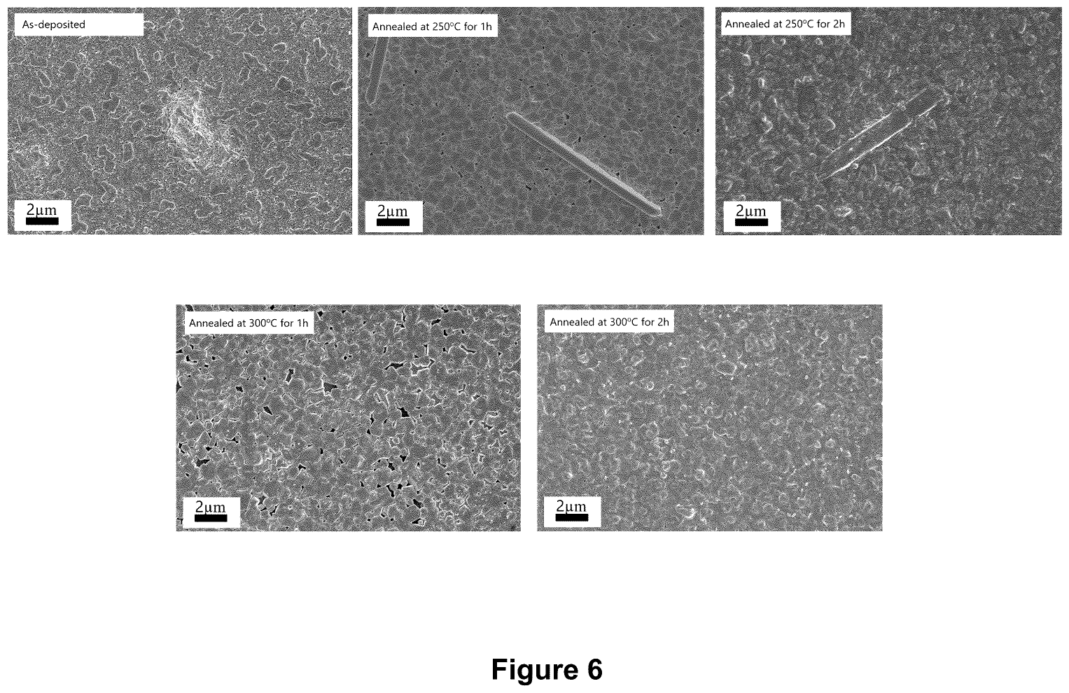

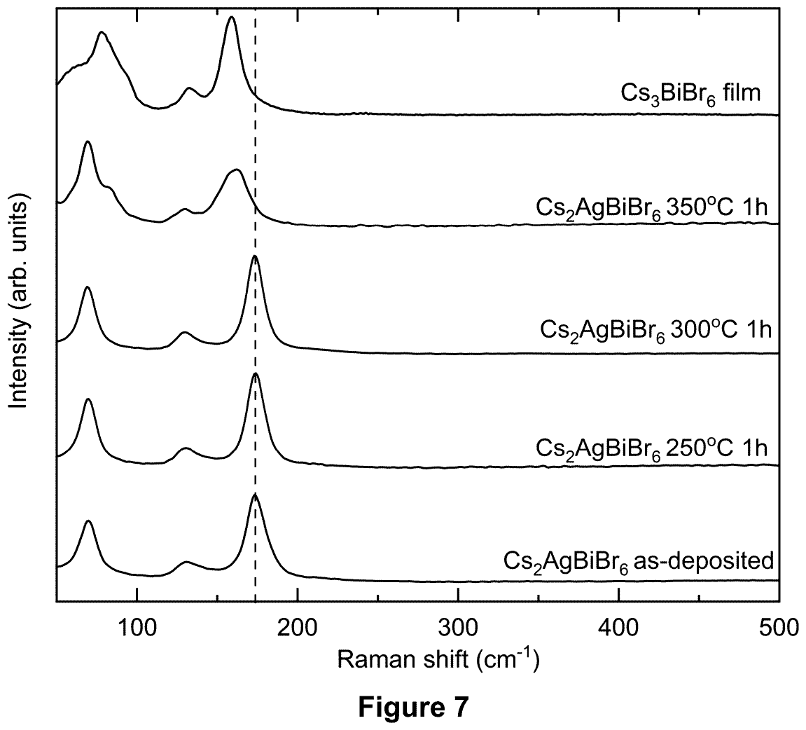

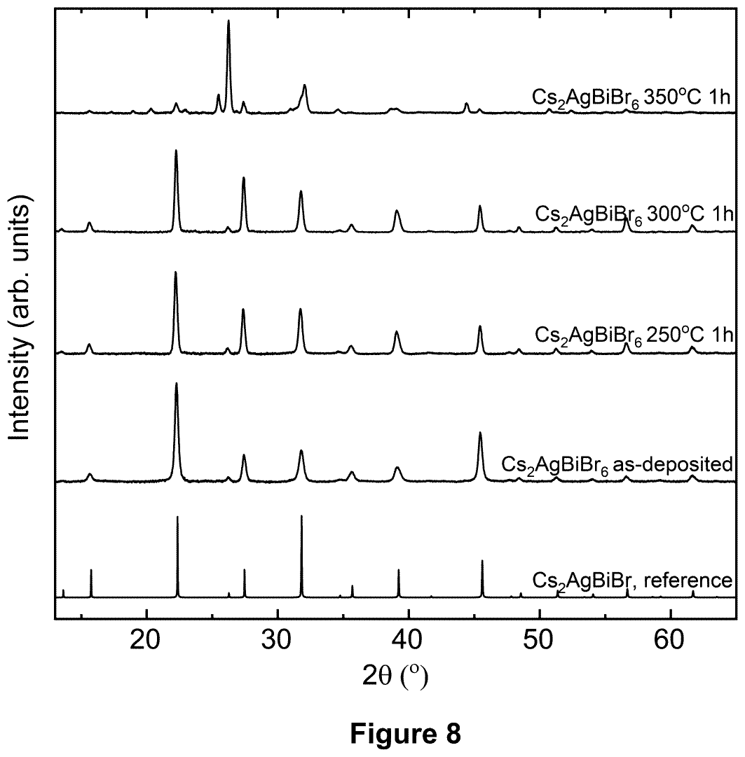

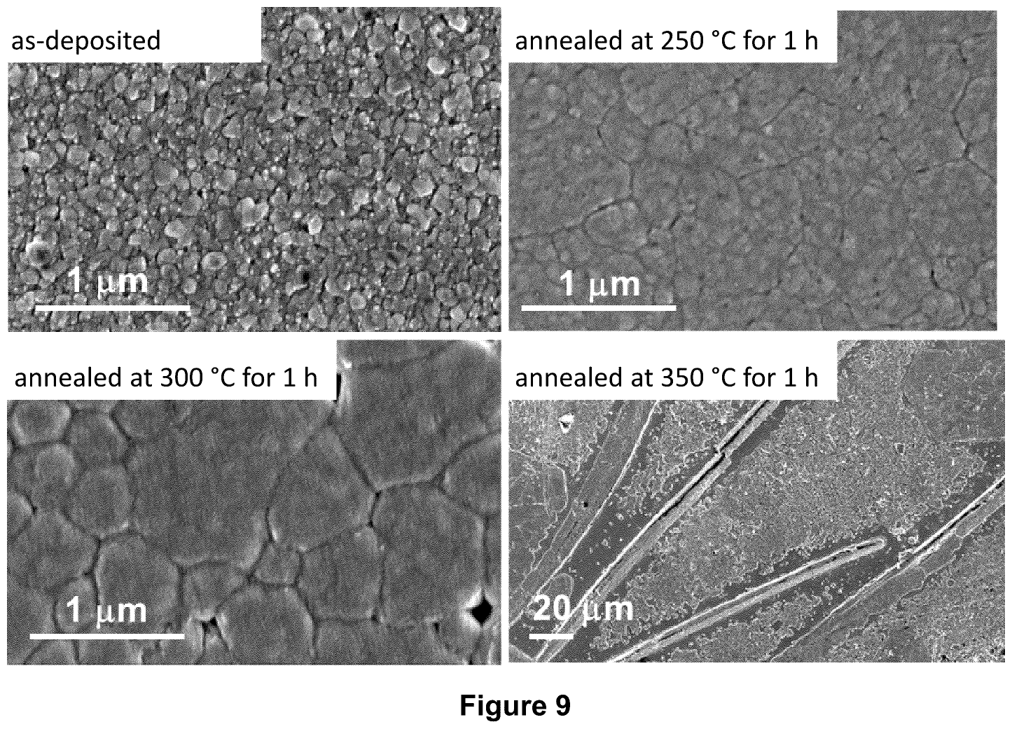

Physical vapor deposition (PVD), specifically evaporation, was employed to synthesize Yb-doped Cs₂AgBiBr₆ thin films from CsBr, BiBr₃, AgBr, and YbBr₃, whose evaporation rates were measured using separate quartz crystal microbalances. Films were annealed post-deposition in a nitrogen-filled glovebox at 250-350° C. CsBr, BiBr₃, and AgBr evaporation rates and deposition durations were set to produce nominally stoichiometric Cs₂AgBiBr₆. Yb doping was varied between 0% and 14% by controlling the YbBr₃ evaporation rate. The Yb concentration is reported as a percent of Bi lattice positions in stoichiometric Cs₂AgBiBr₆ (i.e., to deposit a 3% Yb-doped Cs₂AgBiBr₆ the ratio of YbBr₃ molar flux to BiBr₃ molar flux was set to 0.03). X-ray diffraction patterns of Yb-doped films annealed at 300° C. for one hour are shown in FIG. 3. All films crystallize with the Cs₂AgBiBr₆ cubic structure (#225, Fm3̅m). Annealing helps the precursors react completely and form the target Cs₂AgBiBr₆ structure. Otherwise, unreacted precursors (e.g., AgBr) and other impurity phases, such as Cs₃Bi₂Br₉, are still present in the as-deposited films (FIG. 4 and FIG. 5). A small shift to higher 2θ values was observed in the XRD patterns for Yb-doped films compared to the undoped Cs₂AgBiBr₆ film. Lattice parameters calculated from XRD data show a small unit cell contraction when Yb up to 10% is introduced to the perovskite structure (Table 1), which is reasonable because Yb³⁺ ions (101 pm) have a smaller radius than both Bi³⁺ (117 pm) and Ag⁺ (129 pm) ions. Films with 10 and 14% Yb show XRD peaks from AgBr at 26.8° and 31.0°. One explanation is that Yb³⁺ substitutes the Ag⁺ ions, and the replaced silver forms AgBr as an impurity phase in the film. Another possibility is that adding Yb to Cs₂AgBiBr₆ destabilizes the structure and decomposes to AgBr and other impurity phases. Indeed, in addition to AgBr, Cs—Ag—Br ternary phases were detected in Cs₂AgBiBr₆ films when Yb concentration is 10% or greater (FIG. 6). The AgBr and ternary Cs—Ag—Br phases are reported as commonly observed impurity phases during colloidal synthesis of Cs₂AgBiBr₆. The Cs—Ag—Br impurity phases were more prevalent in as-deposited films and films annealed at 250° C. than in films annealed at 300° C. (FIG. 6). The Cs₂AgBiBr₆ films decompose at 350° C., (FIG. 7, FIG. 8, and FIG. 9), making about 300° C. a suitable optimized annealing temperature.

TABLE 1
Lattice parameters (a) of undoped and Yb-
doped Cs₂AgBiBr₆ films from XRD data.

| % Yb | a (Å) |
|---|---|
| 0 | 11.282 |
| 3 | 11.252 |
| 5 | 11.278 |
| 8 | 11.270 |
| 10 | 11.272 |
| 14 | 11.296 |

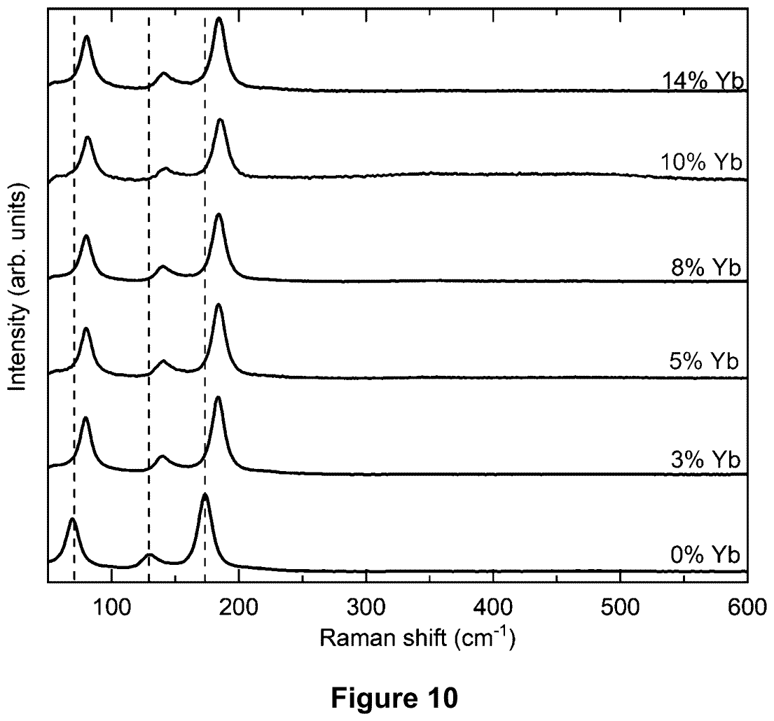

Comparison of Raman scattering from undoped and Yb-doped films confirmed ytterbium incorporation. Raman spectrum of an undoped Cs₂AgBiBr₆ film consists of three peaks at 173, 130, and 69 cm⁻¹ (FIG. 10), which agrees well with the reported Raman spectra. Three vibrational modes, A_{1g}, E_{g}, and T_{2g}, either of [BiBr₆]³⁻ or of [AgBr₆]⁵⁻ octahedra, have been assigned to the peaks at 173, 130, and 69 cm⁻¹, respectively (Steele, J. A. et al., ACS Nano. 2018, 12 (8), 8081-8090). Doping Cs₂AgBiBr₆ with Yb shifts these peaks to higher wavenumbers: 69 to 80, 130 to 140, and 173 to 184 cm⁻¹ at 14% Yb. Since Raman peaks shift to higher wavenumbers when the structure is compressed, the observed shifts in Yb-doped films confirm Yb³⁺ ions do indeed substitute the octahedral cations in the perovskite structure creating compression strain on the unit cell. Raman spectra from the annealed films do not show any impurity phase peaks (FIG. 10). In contrast, Raman spectra from the as-deposited films show peaks that can be assigned to Cs₃Bi₂Br₉ (FIG. 5), suggesting that the impurity phases are present in the as-deposited films but are below the detection limit of Raman scattering in films annealed at 300° C.

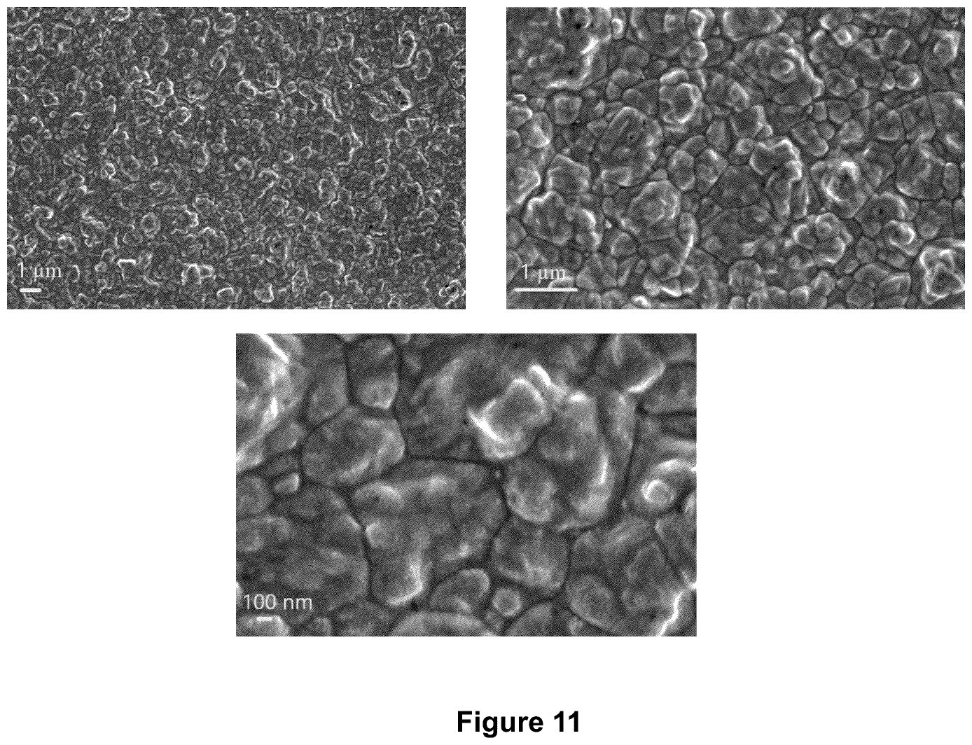

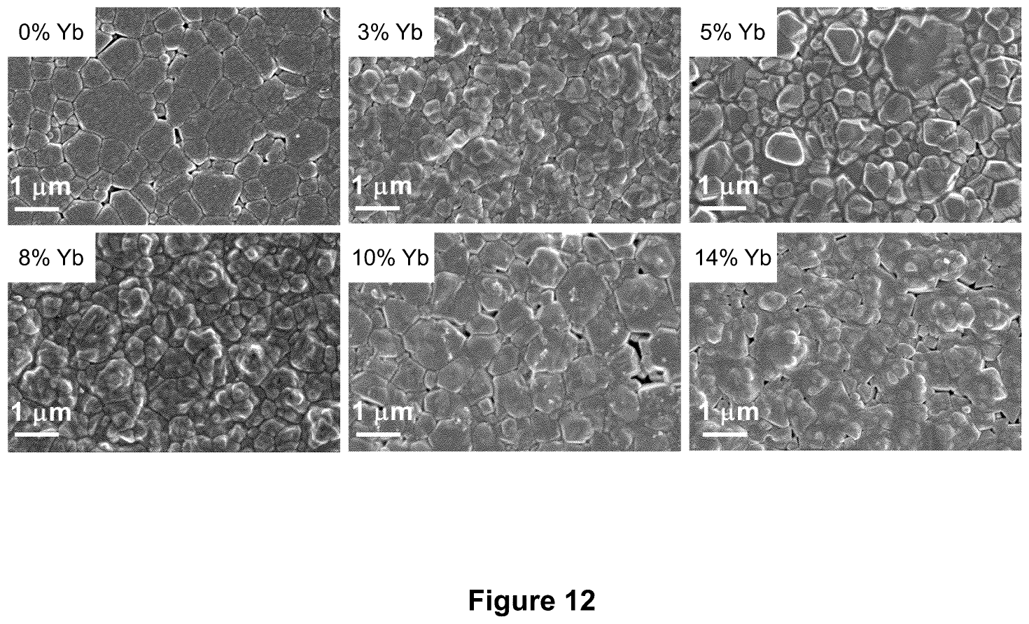

Scanning electron microscopy (SEM) images of annealed Yb-doped Cs₂AgBiBr₆ films show uniform films with grain sizes of a few hundred nanometers (FIG. 11 and FIG. 12). As-deposited films contain poorly defined small (<100 nm) Cs₂AgBiBr₆ grains and larger domains with different morphology and composition (FIG. 6) consistent with unreacted precursors and impurity phases. The Cs₂AgBiBr₆ grains grow and become more well-defined while the unreacted precursors and impurity phases are converted to Cs-₂AgBiBr₆ and disappear during the annealing step. Compositional analysis by EDS also indicates the presence of Yb in the films. For example, the composition of 8% Yb—Cs₂AgBiBr₆ film is 0.6% Yb, 9.2% Bi, 10.3% Ag, 18.5% Cs and 61.4% Br, close to the values expected from the precursor fluxes (0.8% Yb, 9.7% Bi, 9.7% Ag, 19.4% Cs and 60.5% Br). In summary, XRD, Raman, and SEM-EDS data show that up to 14% of Yb were incorporated into the Cs₂AgBiBr₆ film while the perovskite host's cubic structure is still maintained.

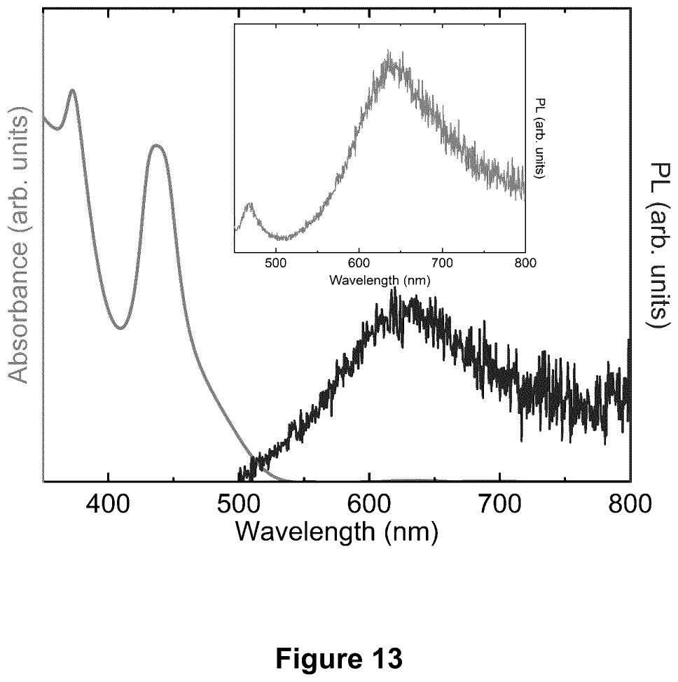

FIG. 13 shows the absorption and photoluminescence spectra of an undoped Cs₂AgBiBr₆ thin film. The absorption starts rising at 560 nm, suggesting a bandgap of 2.2 eV, in the reported range of 1.8-2.3 eV for the indirect bandgap of this material (Kentsch, R. et al, J. Phys. Chem. C. 2018, 122, 25940-25947). The absorption peak at 435 nm matches reported data for nanocrystals (Creutz, S. E. et al, Nano Lett. 2018, 18, 1118-1123; Bekenstein, Y. et al, Nano Lett. 2018, 18, 3502-3508; Dey, A. et al, ACS Nano. 2020, 14, 5855-5861), and thin films (Wright, A. D. et al, J. Phys. Chem. Lett. 2021, 12, 3352-3360). In contrast, absorption measured on single crystals rises monotonically without any peaks (Steele, J. A. et al, ACS Nano. 2018, 12 (8), 8081-8090; Zelewski, S. J. et al, J. Mater. Chem. C. 2019, 7, 8350-8356; Slavney, A. H. et al, J. Am. Chem. Soc. 2016, 138, 2138-2141), likely a result of absorption saturation for thick samples. The absorption peak at 435 nm has been attributed to an exciton (Palummo, M. et al, ACS Energy Lett. 2020, 5, 457-463; Wright, A. D. et al, J. Phys. Chem. Lett. 2021, 12, 3352-3360; Yang, B. et al, Angew. Chem. Int. Ed. 2018, 57, 5359-5363; Wu, C. et al, Adv. Sci. 2018, 5, 1700759), or the s-p transition on Bi (Igbari, F. et al, Nano Lett. 2019, 19, 2066-2073). The main objection to assigning this feature to an exciton has been the lack of a blue-shift in its wavelength as nanocrystal size is reduced (quantum confinement effect). However, it is not expected for Cs₂AgBiBr₆ to exhibit absorption blue-shift due to quantum confinement because the exciton Bohr radius in Cs₂AgBiBr₆ is estimated between 0.3 to 0.5 Å, smaller than one Cs₂AgBiBr₆ unit cell. Interestingly, Cs₃Bi₂Br₉, with a corner-shared [BiBr₆]³⁻ octahedra, also has an exciton absorption peak at 435 nm, associated with the localized exciton on [BiBr₆]³⁻ octahedra (Tran, M. N. et al, J. Mater. Chem. A. 2021, 9, 13026-13035). The similarity between the two structures and their absorption features suggests that the Cs₂AgBiBr₆ absorption peak at 435 nm is also associated with localized excitons on the [BiBr₆]³⁻ octahedra.

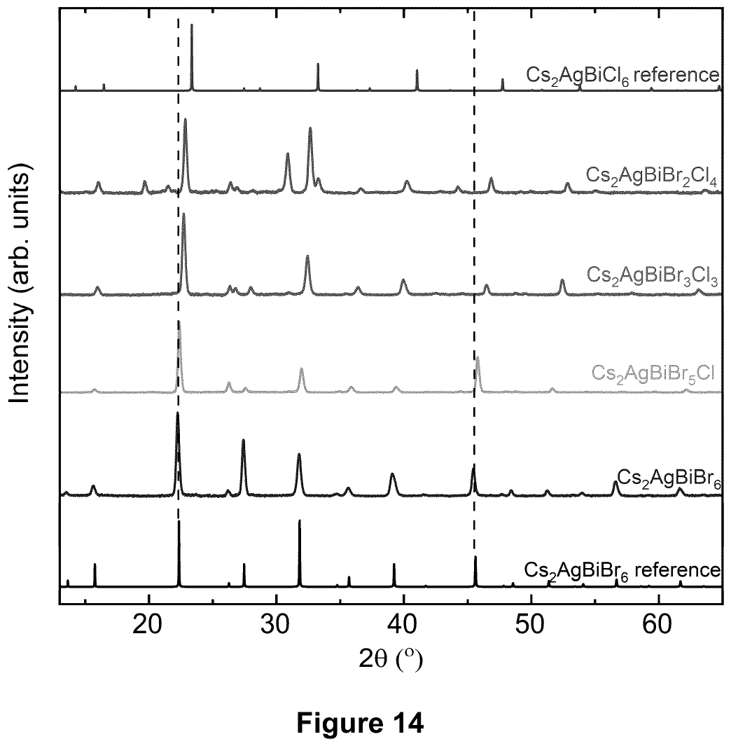

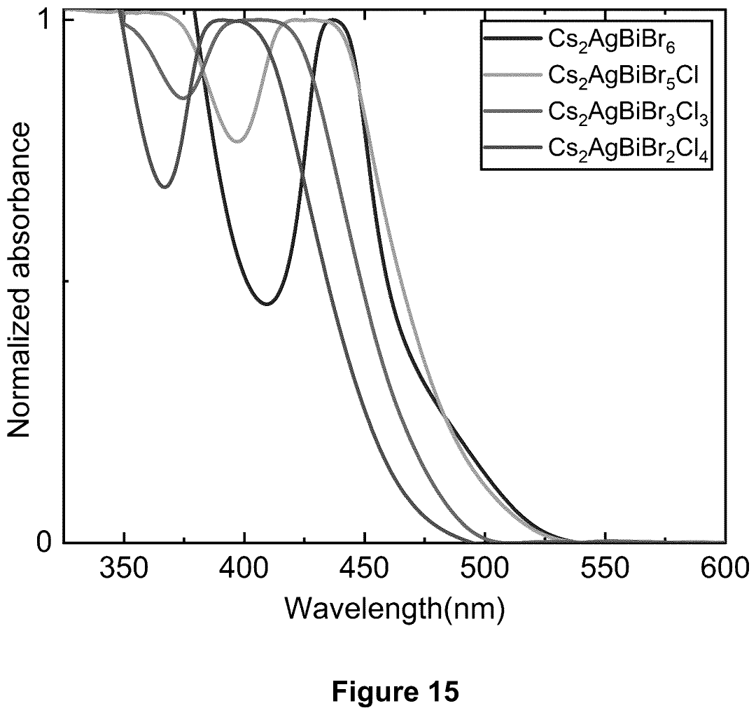

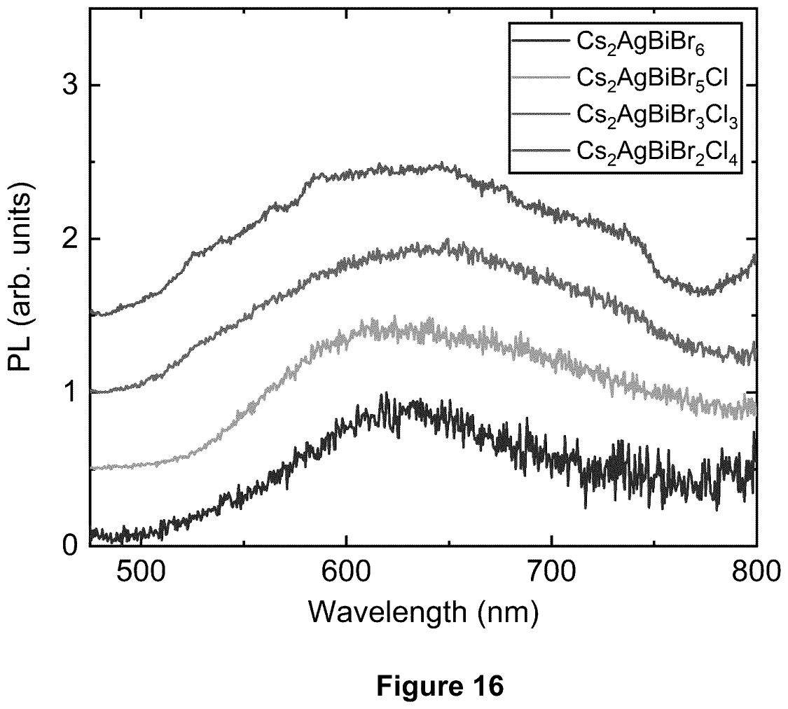

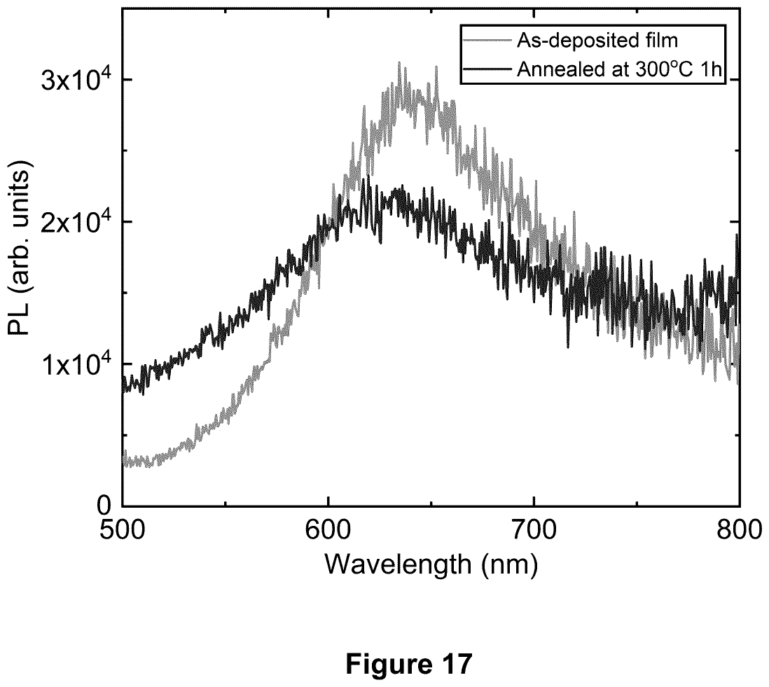

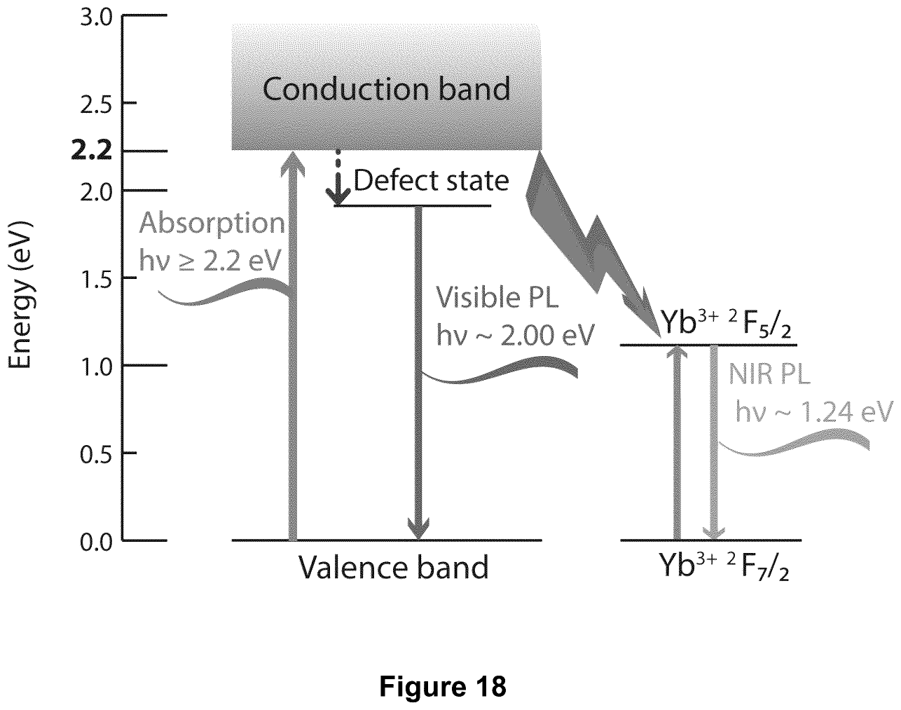

Photoluminescence (PL) from the undoped Cs₂AgBiBr₆ thin film is weak and comprises a broad emission centered around 630 nm (FWHM=150 nm) (FIG. 13). This broad emission has been observed in multiple studies (Steele, J. A. et al, ACS Nano. 2018, 12 (8), 8081-8090), but the origin is still under debate: it has been associated with band-edge transition, self-trapped excitons, and defect-related recombination. Cs₂AgBiCl_{y}Br_{6-y} was deposited and the bandgap of Cs₂AgBiBr₆ shifted to higher energies by substituting bromine with chlorine to examine the origin of this orange PL. XRD patterns from Cs₂AgBiCl_{y}Br_{6-y} thin films indicate that the halides are mixed throughout the films (FIG. 14). As shown in FIG. 15, the blue absorption peak shifts from 435 nm for y=0 to 393 nm for y=4 as the bandgap increases with chlorine substitution. However, the emission does not shift and remains centered at ˜630 nm for all Cs₂AgBiCl_{y}Br_{6-y} films (FIG. 16). The intensity decreases with annealing (FIG. 17). The lack of shift and decreasing intensity with annealing strongly suggests that the 630 nm emission originates from defects and is not due to a band-to-band transition (FIG. 18). There is also a weak emission peak at 470 nm from the as-deposited undoped Cs₂AgBiBr₆ thin-film, but it disappears after annealing (FIG. 13). The disappearance with annealing supports a defect origin. This Cs₂AgBiBr₆ emission peak at 470 nm was observed and attributed to a defect-related bound exciton. Cs₃Bi₂Br₉ thin film also has an emission peak at ˜470 nm, assigned to emission from excitons trapped on defects. The fact that both Cs₂AgBiBr₆ and Cs₃Bi₂Br₉ thin films have an absorption peak at 435 nm and an emission peak at 470 nm indicates that the absorption and subsequent emission have a common origin and are associated with excitons forming via light absorption and then getting trapped and recombining on defects. The obvious candidate is a localized exciton on [BiBr₆]³⁻ octahedra, forming upon light absorption and becoming trapped on a Bi vacancy, V_{Bi}, before emission. Cation vacancies are a feature of the Cs₃Bi₂Br₉ vacancy-ordered perovskite structure. In Cs₂AgBiBr₆, vacancies are expected to be annealed since the perfect structure has an Ag or Bi cation in all octahedra.

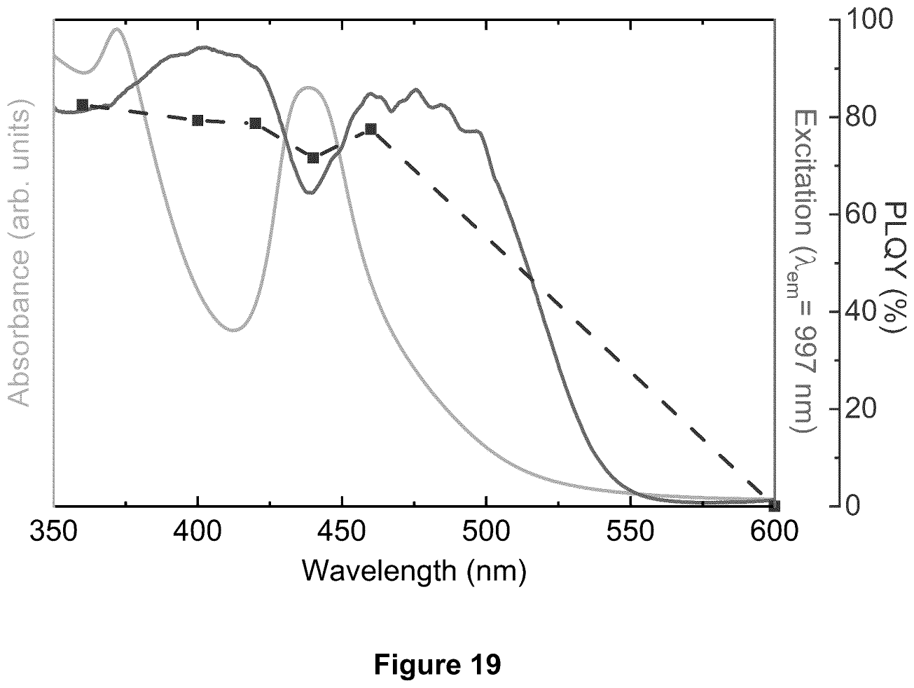

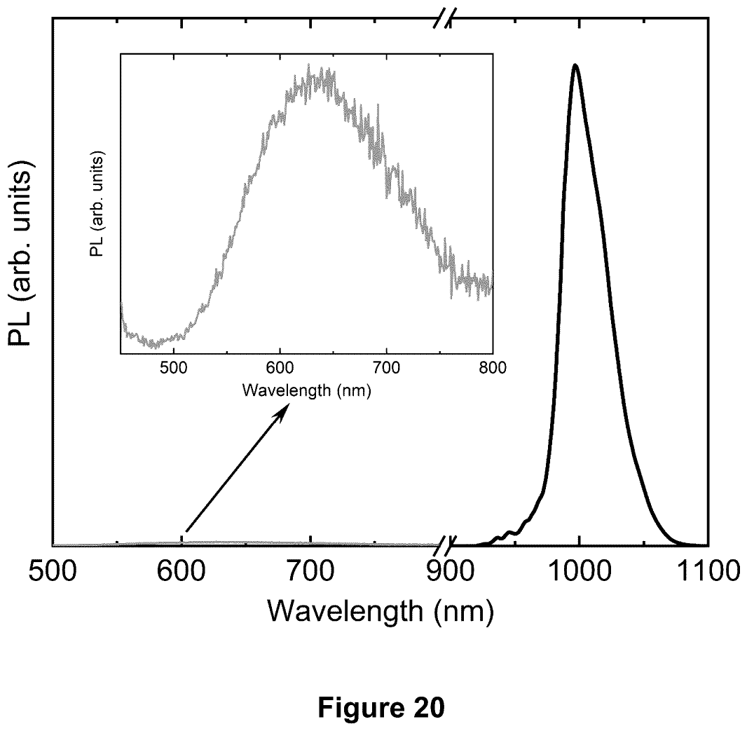

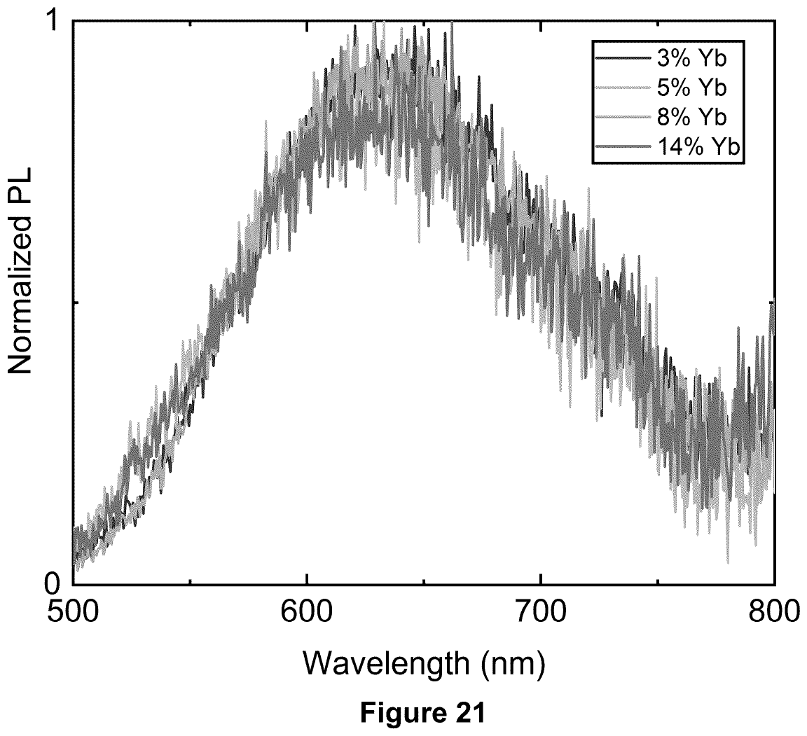

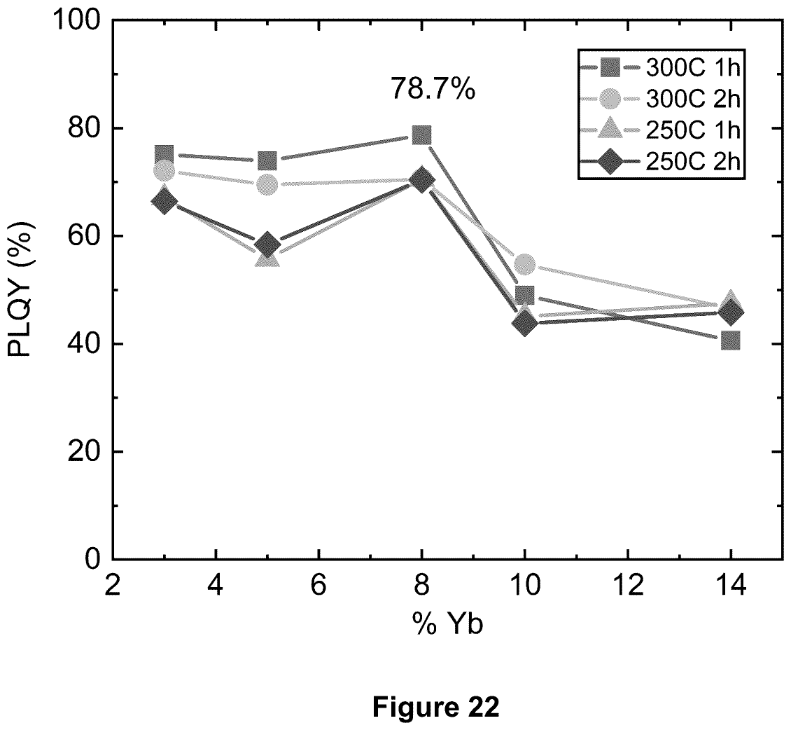

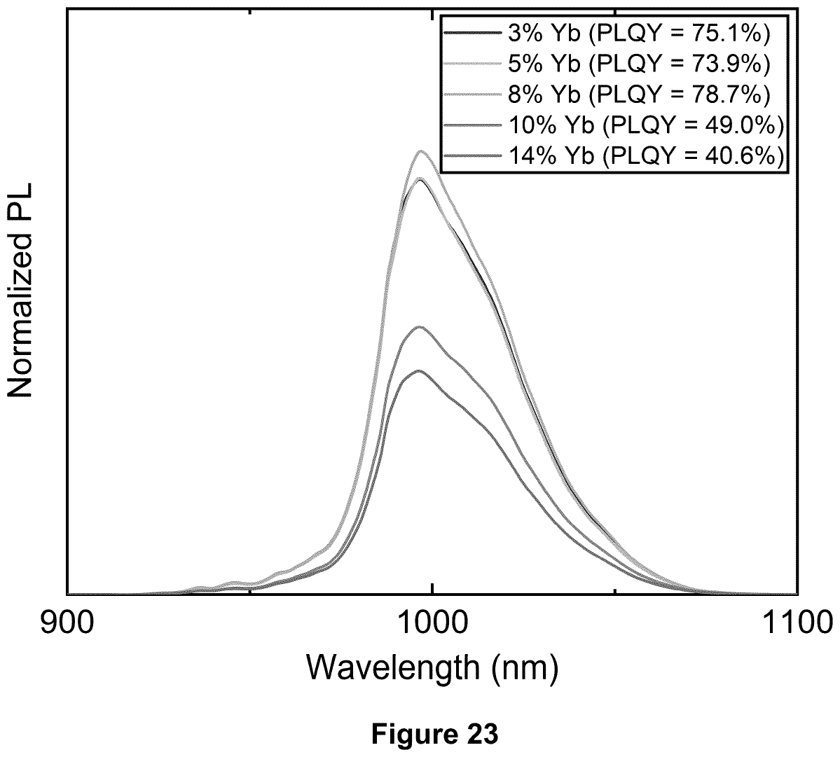

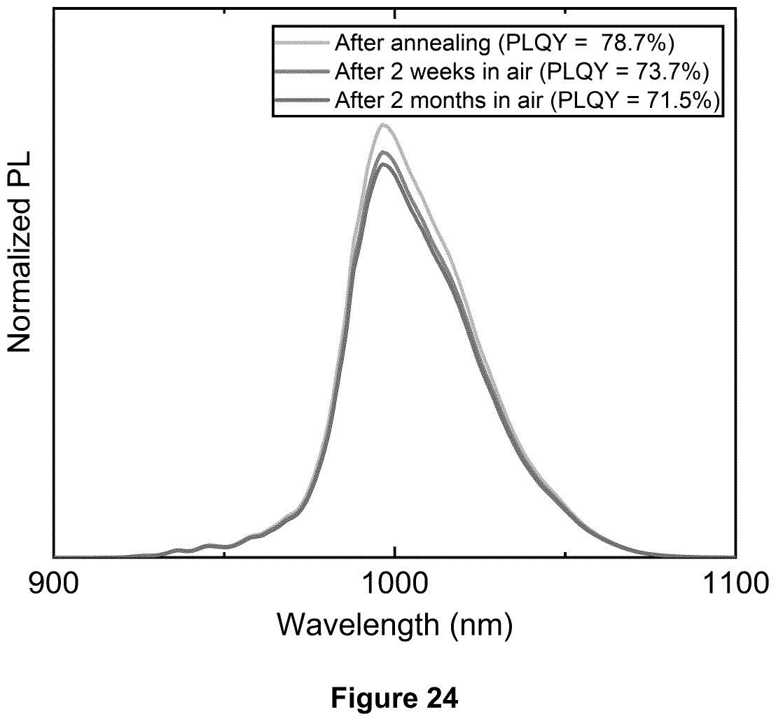

Doping Yb into Cs₂AgBiBr₆ did not affect the optical absorption. Yb-doped Cs₂AgBiBr₆ thin films still have an absorption peak at 435 nm, with the onset at ˜560 nm (FIG. 19), and the bandgap remains unchanged. The energy transfer from the Cs₂AgBiBr₆ host to the Yb³⁺ is efficient, and all films doped with ytterbium emit strongly in the NIR (1.24 eV), in addition to the weak orange emission from the perovskite host (FIG. 20 and FIG. 21) The NIR emission peak is centered at 997 nm (FWHM=40 nm), the expected Yb^{3+ 2}F_{5/2}→²F_{7/2} electronic transition wavelength. Near-infrared PLQY depends strongly on the Yb concentration and annealing temperature. Films annealed at 300° C. have the highest PLQY, and their PLQYs are stable with time in ambient air (FIG. 22 and Table 2). PLQY of films annealed at 250° C. decreases significantly after exposure to air (Table 2). FIG. 22 shows that increasing the annealing time does not affect PLQY significantly; the difference in PLQY between films annealed for 1 hour and 2 hours is negligible for both annealing temperatures, 250 and 300° C. As shown in FIG. 22 and FIG. 23 high near-infrared PLQY between 73.9 and 78.7% was achieved for films doped with 3 to 8% Yb (excitation wavelength was 420 nm with 10 nm bandwidth). Near-infrared emission decreases sharply when Yb concentration is higher than 8%, with PLQY reducing to 40.6% for films with 14% Yb (FIG. 22). This decrease in PLQY coincides with impurity peaks appearing in XRD of the films with 10 and 14% Yb. Impurity phases and defect states introduce nonradiative relaxation pathways that compete with the energy transfer to Yb, decreasing the NIR emission. Films annealed at 300° C. are stable in the air, and PLQY does not change significantly with time: PLQY of Cs₂AgBiBr₆ film doped with 8% Yb retains 94% of the PLQY after two weeks and 91% after two months without any encapsulation (FIG. 24).

TABLE 2
NIR PLQY of Cs₂AgBiBr₆ films doped with 3% Yb on the
day of the deposition and after one day in the air.
The excitation wavelength was 420 nm with 10 nm bandwidth.
Dependence of one-day stability of PLQY is shown for
different annealing times and temperatures.

| | | | |
|---|---|---|---|
| Annealing | Annealing | PLQY after | PLQY after |
| Temperature | Time | Annealing | one day |

| | | | | |
|---|---|---|---|---|
| 300° C. | 1 | hour | 75.1% | 78.3% |
| 300° C. | 2 | hours | 72.1% | 74.3% |
| 250° C. | 1 | hour | 67.1% | 50.1% |
| 150° C. | 2 | hours | 66.4% | 54.1% |

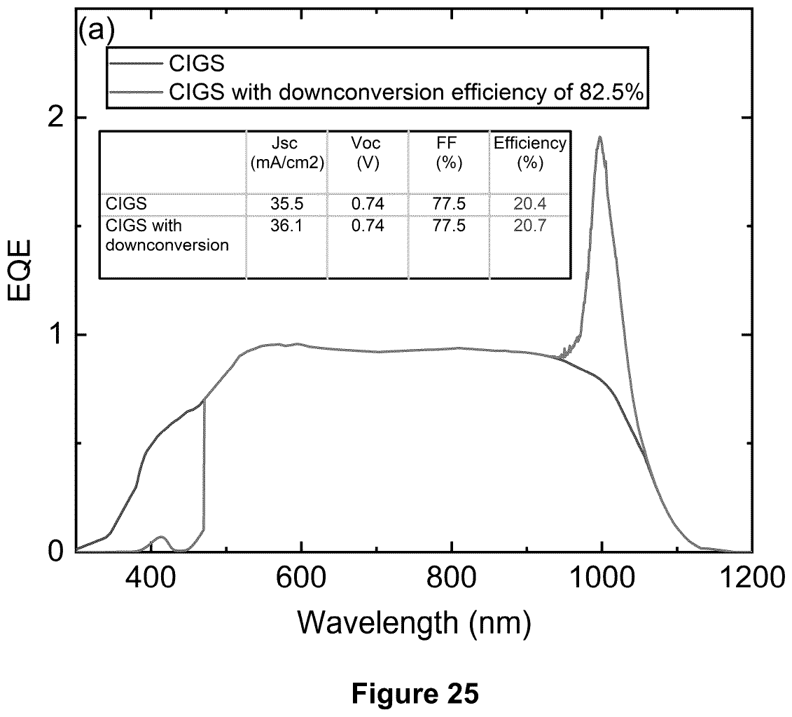

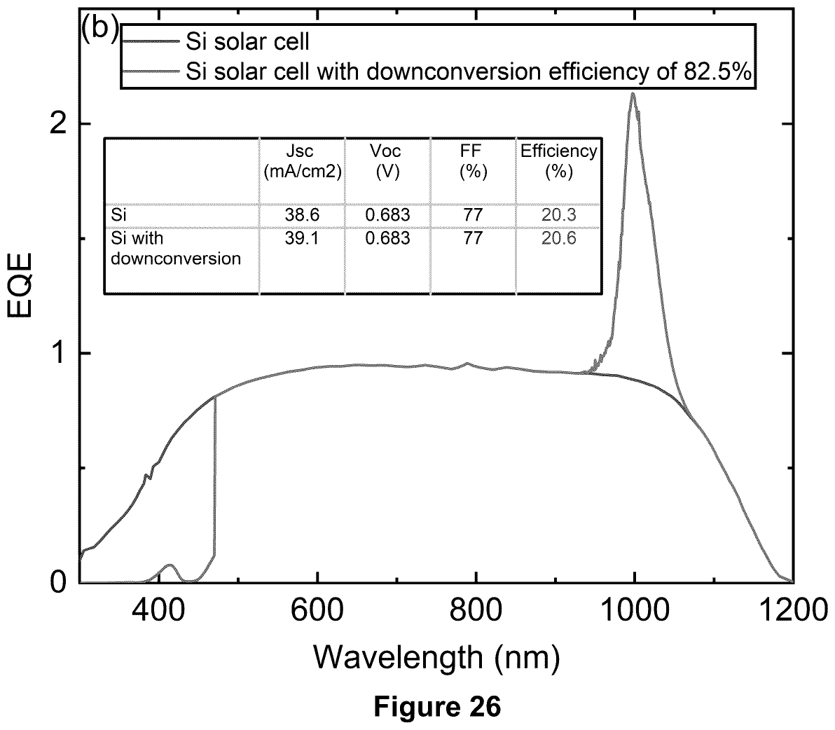

FIG. 19 shows the excitation spectrum of the Cs₂AgBiBr₆ film doped with 8% Yb and annealed at 300° C. for 1 hour (emission wavelength, λₑₘ=997 nm). This film had the highest PLQY, 78.7%, when excited at 420 nm. FIG. 19 also shows the absorption spectrum and PLQY measured at different excitation wavelengths. The excitation spectrum starts rising at 560 nm, the absorption onset, thus confirming that Yb³⁺ ions are not excited by the incident photons but receive energy from the perovskite host, as illustrated in FIG. 18. When a photon with an energy higher than the Cs₂AgBiBr₆ bandgap (˜2.2 eV, or wavelengths lower than 560 nm) is absorbed by the perovskite, it creates an electron-hole pair with the electron being excited to the conduction band. When the electron recombines with the hole, it transfers energy to a nearby Yb³⁺ ion. Electrons in Yb³⁺ ions are excited from the ²F_{7/2} to the ²F_{5/2} state and then emit in the NIR region when they relax down to the ²F_{7/2} state. Thus, a UV-visible photon is downconverted to a NIR photon via the energy transfer from Cs₂AgBiBr₆ to Yb³⁺ ions (FIG. 18). Interestingly, the excitation spectrum dips at 435 nm, where the exciton absorption peaks. However, PLQY remains high, 71.6%, when the film is excited at 440 nm. PLQY reaches the highest value of 82.5% when Cs₂AgBiBr₆ films doped with 8% Yb and annealed at 300° C. are excited at 360 nm. Depositing a layer of a downconversion material with 82.5% PLQY can increase a typical Si solar cell's efficiency from 20.3 to 20.6%, and a CIGS solar cell's efficiency from 20.4 to 20.7% (See FIG. 25 and FIG. 26). Further optimization and increases can lead to greater gains.

In summary, undoped and Yb-doped Cs₂AgBiBr₆ thin films via were synthesized via PVD. The thin films showed efficient energy transfer from the host to the Yb³⁺ ions, which emits 1.24 eV NIR radiation with efficiencies as high as 82.5%. PLQY of Cs₂AgBiBr₆ films doped with 8% Yb and annealed post-deposition at 300° C. remains high even after two months in the air. The perovskite host, Cs₂AgBiBr₆, has an exciton absorption centered at 435 nm, and the bandgap is estimated as 2.2 eV. The weak and broad emission at 630 nm is assigned to defect recombination. Using the record efficiencies reported here as a starting point, further improvements in synthesis conditions of this class of lead-free materials are likely to increase their PLQY towards 100%. This creates new prospects for modifying the solar spectrum by spectrum shifting to increase solar cell efficiencies.

### Experimental Methods

### Thin-Film Deposition

Films were deposited in a glove-boxed physical vapor deposition (PVD) system (Angstrom Engineering) with six evaporation sources. The four precursors, BiBr₃ (99%, Alfa Aesar), AgBr (99.9%, Beantown Chemical), CsBr (99.9%, Acros Organics), and YbBr₃ (hydrate, 99.99%, Alfa Aesar), were loaded into separate RADAK sources and baked overnight at 60, 100, 100, and 110° C., respectively. BiBr₃ was loaded in quartz ampoules, while the others were loaded in alumina ampoules. The glass substrates (25×25 mm²) were cleaned by sonicating in a 1:1 solution by volume of acetone (ACS Grade, VWR) and isopropanol (99.5%, VWR) for 30 minutes, dried in an oven, and cleaned with O₂ plasma for 30 minutes using Expanded Plasma Cleaner PDC-001-HP (Harrick Plasma) before loading them onto the substrate holder. Each precursor's evaporation rate was monitored during the deposition by separate quartz crystal microbalances (QCMs). The substrates' temperatures were not controlled during the deposition. The tooling factors were determined by evaporating CsBr and BiBr₃ separately and obtaining the film thickness from interference fringes in optical transmission. The tooling factors, the ratio of the deposition rate at the substrate to the deposition rate at the QCM expressed as %, were 39.7 and 42.9 for CsBr and BiBr₃, respectively. The tooling factor of CsBr was also used for YbBr₃ and AgBr.

During the deposition of Cs₂AgBiBr₆ films, BiBr₃, AgBr, and CsBr were co-evaporated onto glass substrates at 1.00, 0.37, and 1.21 Å/s, respectively. With these deposition rates, the ratio of CsBr to BiBr₃ to AgBr molar flux is 2:1:1. The CsBr, BiBr₃, and AgBr source temperatures were the manipulated variables to keep the evaporation rates constant and were ≈555, 140, and 650° C., respectively. The controller adjusts the temperature around these values to keep the deposition rate constant at the setpoints.

For Yb-doped Cs₂AgBiBr₆ films, three precursors, BiBr₃, AgBr, and YbBr₃, were co-deposited on glass substrates. CsBr was deposited on top of this BiBr₃—AgBr—YbBr₃ layer. BiBr₃ and AgBr evaporation rates were kept constant at 1.00 Å/s and 0.37 Å/s, respectively, while the YbBr₃ evaporation rate was varied from 0.03 to 0.14 Å/s to change the amount of Yb doping. The YbBr₃ source temperature ranged from 627 to 688° C., depending on the evaporation rate and precursor amount in the ampoule. The CsBr evaporation rate was 1.21 Å/s. The system base pressure was 6×10⁻⁷ Torr, while the chamber pressure rose to ≈10⁻⁶ Torr during the deposition. Each layer was deposited for 30 minutes, resulting in 490±10 nm thick films for Cs₂AgBiBr₆. The optical absorption spectrum was obtained from thinner films deposited for 15 minutes to avoid saturation. Films were annealed on a hot plate in the glovebox at different temperatures and for different durations.

For Cs₂AgBiCl_{6-y}Br_{y} thin films, chloride salts were used along with bromide salts to achieve the target halide ratio: Cs₂AgBiClBr₅ films were deposited using AgCl, BiBr₃ and CsBr; Cs₂AgBiCl₃Br₃ films were deposited using AgCl, BiBr₃ and CsCl; Cs₂AgBiCl₄ Br₂ films were deposited using AgCl, BiCl₃ and CsBr. The evaporation rates of AgCl, BiBr₃, BiCl₃, CsBr and CsCl were 0.33, 1.00, 0.85, 1.21 and 1.07 Å/s, respectively. Precursors were co-evaporated onto glass substrates for 30 minutes, and the films were then annealed at 300° C. for one hour.

### Thin-Film Characterization

All films were characterized under ambient conditions at room temperature. Photoluminescence (PL) spectra were measured using a QuantaMaster-8075-21 (Horiba) spectrophotometer. Visible PL from all films was excited at 420 nm (5 nm bandwidth) with double monochromator filtered emission from a Xe-arc lamp and detected using a PMT detector. Near-infrared PL was excited at 420 nm for all films. For the film with the highest PLQY (8% Yb—Cs₂AgBiBr₆), the excitation wavelength was varied between 360 to 600 nm to examine the PLQY dependence on the excitation wavelength. NIR PL was detected using a liquid nitrogen-cooled InGaAs detector. PLQY was measured using an integrating sphere (Quanta-Phi, Horiba), and the lamp power was measured using Power Meter 843-R and 818-UV photodetector (Newport). X-ray diffraction (XRD) patterns from the films were recorded using a Bruker D8 Discover General Area Detector Diffraction System (GADDS) equipped with a Cu-Kα source. Raman spectra were acquired using a Thermo Scientific DXR Raman microscope. Thin films were excited with a 785 nm laser, and Raman scattering in the range of 50-1800 cm−1 was collected with a 50× Olympus objective, dispersed using a high resolution (2 cm−1) grating, and detected with a CCD detector. Films were examined using a Merlin field emission scanning electron microscope (Carl Zeiss, 5 kV, 110 pA). Their average composition over an area of approximately 10 μm² was determined using energy-dispersive X-ray spectroscopy (Oxford Instruments EDS) and vendor-provided sensitivity factors. Optical absorptions of the films were recorded using an Agilent Cary 5000 UV-Vis-NIR in the 200-2000 nm range.

Calculation of the Minimum Near-Infrared Photoluminescence Quantum Yield Needed to Increase the Efficiency of a Solar Cell with a Given External Quantum Efficiency

Consider a solar cell with power conversion efficiency, η, external quantum efficiency, EQE(λ), open-circuit voltage, V_{OC} and fill factor FF. When this solar cell is coated with a material that downconverts UV-blue photons to NIR photons, the downconversion (DC) material absorbs in the UV-blue region of the electromagnetic spectrum and reemits in the near-infrared (NTR) region. The new downconverted photon flux the solar cell receives is

$${ϕ}^{*} ( λ ) = ϕ ( λ ) - A ( λ ) + {η}_{PLQY} f ( λ ) {\int }_{0}^{{λ}_{g , p}} A ( λ ) d λ \qquad ( 1 )$$

where ϕ(λ) is the unconverted solar photon flux (e.g., AM1.5), λ is the wavelength (nm), A(λ) is the film's absorbance, η_{PLQY} is the NIR photoluminescence quantum yield, and f(λ) is the line shape of the NIR emission modeled as a Gaussian function

$$f ( λ ) = \frac{1}{\sqrt{2 π} σ} {e}^{- \frac{{( λ - {λ}_{o} )}^{2}}{2 {σ}^{2}}} \qquad ( 2 )$$

whose center peak wavelength (λ₀=997 nm) and width (2\sqrt{2 ln2} σ=40 nm) are determined by fitting a typical experimental NIR emission spectrum. For Cs₂AgBiBr₆, the wavelength corresponding to the perovskite bandgap, λ_{g,p}, is 470 nm. The short circuit current created from this downconverted photon flux is given by

$${J}_{sc}^{*} = e {\int }_{0}^{{λ}_{g , Si}} {ϕ}^{*} ( λ ) EQE ( λ ) d λ \qquad ( 3 )$$

where e is the electron charge and EQE(λ) is the solar cell's external quantum efficiency. In these calculations, the EQE(λ) data for Si and CIGS was digitized and used. The calculations rely on the assumption that open-circuit voltage and fill factor, V_{OC} and FF remain the same and constant values are used. The new power conversion efficiency of the solar cell receiving the downconverted solar spectrum is

$${η}^{*} = {J}_{sc}^{*} \times {V}_{OC} \times FF . \qquad ( 4 )$$

Using these equations, the minimum η_{PLQY} required for η* to exceed the original efficiency of the solar cell without the downconverting coating can be calculated. For the solar cells and V_{OC}, FF and EQE(λ) values from Friedlmeier, T. M. et al. (IEEE 42nd Photovoltaic Specialist Conference. 2015, 1-3) and from Mazzarella, L. et al. (Appl. Phys. Lett. 2015, 106, 023902), values of 69% and 67% are obtained for typical Si and CIGS solar cells, respectively.

### Bohr Radius Calculation

Exciton Bohr radius is given by

$${a}_{ex} = {ε}_{r} \frac{{m}_{o}}{{μ}_{r}} {a}_{B} \qquad ( 5 )$$

where εᵣ is the dielectric constant (εᵣ˜5.8),² mₒ is the mass of an electron, a_{B}=0.053 nm is the Hydrogen Bohr Radius and μᵣ is the reduced mass, given by

$${μ}_{r} = \frac{{m}_{e} {m}_{h}}{{m}_{e} + {m}_{h}} \qquad ( 6 )$$

Taking mₑ=0.37mₒ and mₕ=0.14mₒ, aₑₓ≈0.03 nm. Taking mₑ=0.36mₒ and mₕ=0.33 mₒ, aₑₓ≈0.05 nm. Both these estimates are much smaller than the unit cell dimensions.

### Example 2: Reactive Physical Vapor Deposition of Yb-Doped Lead-Free Double Perovskite Cs₂AgBiBr₆ with 95% Photoluminescence Quantum Yield

Yb-doped Cs₂AgBiBr₆ is a promising lead-free halide double perovskite that can be used as a downconverting coating on silicon solar cells to redshift UV and blue photons to near-infrared where the quantum efficiencies are larger. Photoluminescence quantum yield (PLQY) of Yb-doped Cs₂AgBiBr₆ thin films synthesized via physical vapor deposition depends strongly on how the substrate temperature changes during deposition, which determines the amount of Bi incorporated into the film. Yb-doped Cs₂AgBiBr₆ films with PLQY as high as 95% were deposited with excess BiBr₃ and by ramping substrate temperature during the deposition. Ramping the substrate temperature reduces BiBr₃ loss from the film by promoting reactions that form Cs₂AgBiBr₆. The films retain 93% of their initial PLQY values after one month.

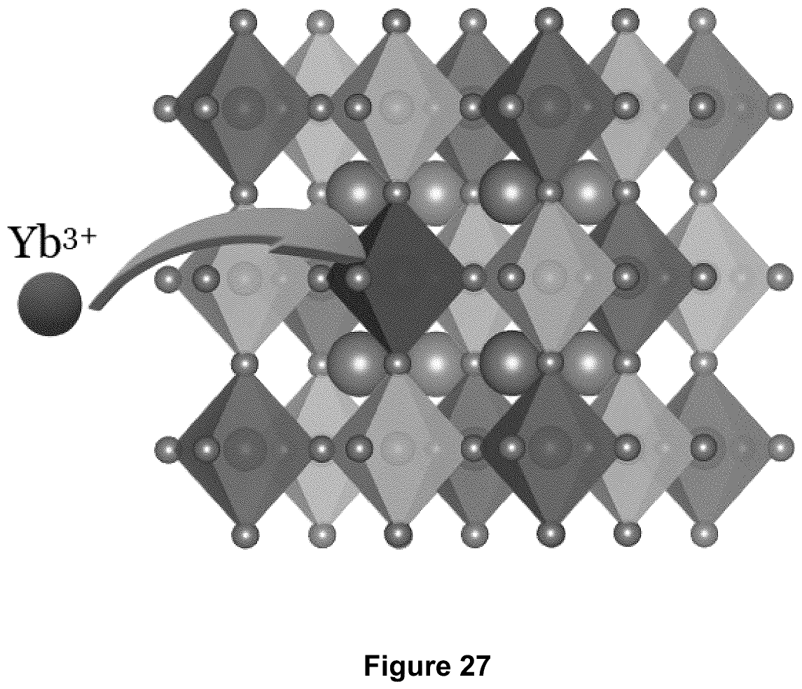

Cs₂AgBiBr₆ has a stable cubic structure at room temperature (#225, Fm 3̅ m, a=11.2499 Å) (Gloeckler, M. Sites, J. R. J. Phys. Chem. Solids. 2005, 66, 1891-1894), and an indirect bandgap of ˜2.2 eV. Yb³⁺ ions are hypothesized to replace Bi³⁺ and Ag⁺ ions in the 3D network of corner-sharing [AgBr₆]⁵⁻ and [BiBr₆]³⁻ octahedra which alternate periodically in the Cs₂AgBiBr₆ structure (FIG. 27). An electron-hole pair is created when Cs₂AgBiBr₆ absorbs a photon with energy greater than its bandgap (˜2.2 eV, or 560 nm). When the electron relaxes to the valence band edge, it simultaneously transfers the energy to a nearby Yb³⁺ ion. in the crystal structure (which are determined by the synthesis conditions. The synthesis of Yb-doped Cs₂AgBiBr₆ thin films using physical vapor deposition (PVD) and the effects of Yb³⁺ concentration and annealing conditions on the PLQY was discussed in Example 1, above. The dependence of PLQY on the substrate temperature and, in particular, the surprising dependence of PLQY on transient heating, is reported herein. Specifically, the highest PLQY values are obtained when the substrate temperature is ramped during the deposition, an effect that can be traced to the need to balance the reactions of the precursors to form the film and BiBr₃ desorption, which both increase with increasing temperature but the former is desired but the latter is undesired.

### Effect of Substrate Temperature on NIR PLQY

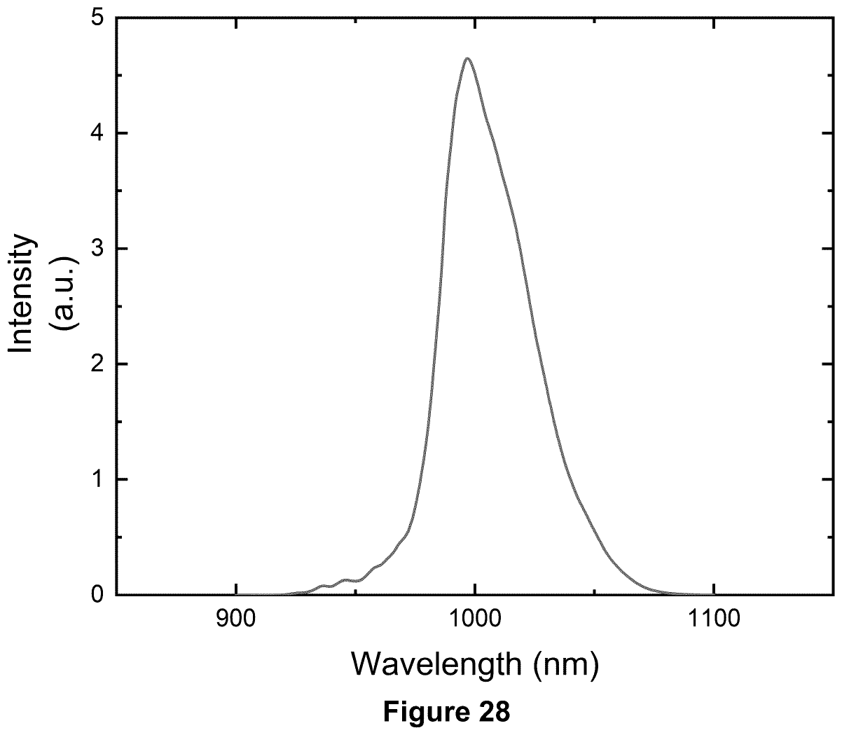

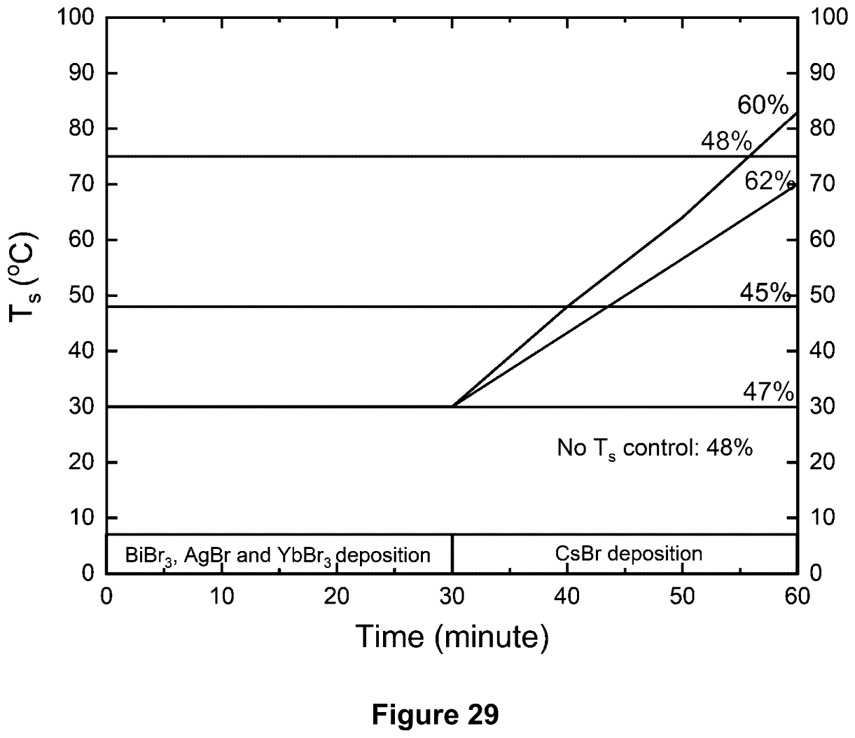

When Yb is doped into Cs₂AgBiBr₆ films, they emit strongly in the near-infrared region, as shown in FIG. 28. The emission peak is centered at 997 nm with FWHM=40.5 nm, the signature emission of the Yb^{3+ 2}F_{5/2}→²F_{7/2} electronic transition. FIG. 29 shows the NIR PLQY from nominally stoichiometric Yb-doped (8% Yb) Cs₂AgBiBr₆ films deposited with no substrate temperature control, at constant substrate temperature (30, 48, and 75° C.) and with the substrate temperature ramped to 70 or 83° C. The substrate temperature was not increased to values higher than 83° C. to prevent the re-evaporation and significant loss of BiBr₃. In the crucibles, BiBr₃ starts evaporating at ≈65° C. at 0.1 Å/s, and BiBr₃ could re-evaporate from the substrates if the temperature ramp is too fast and the final value is too high. FIG. 29 shows the substrate temperature as a function of time during these depositions and the corresponding PLQY of the resulting films after annealing in the nitrogen-filled glove box at 300° C. for one hour. When the temperature is kept constant at 30, 48, and 75° C., the PLQYs are 47, 45, and 48%, respectively. When the temperature is not controlled, PLQY is 48%. The thermal sources heat the substrates radiatively when the films are deposited without controlling the temperature. However, the temperature increase is expected to be negligible due to the substrate stage's large size and thermal inertia. Therefore, the substrate temperature remains close to 30° C. even when not controlled at 30° C. Indeed, the PLQY, 48%, is nearly the same as when the substrate temperature is controlled at 30° C., 47%. Surprisingly, the factor that affects PLQY the most is the ramping of the temperature and not the temperature itself. For example, when the substrate temperature is kept constant at 75° C. throughout the process, PLQY is 48%. However, when the temperature is ramped to 70 or 83° C., PLQY increases to 61-62% (FIG. 29).

The importance of temperature ramping suggests that the PLQY may be determined by competing processes whose rates have different temperature dependencies. First, CsBr must react with the underlying AgBr—BiBr₃—YbBr₃ layer to form Cs₂AgBiBr₆. The precursors may not completely react at low temperatures, but their reaction rates increase with increasing temperature. Second, BiBr₃ must remain in the film and not re-evaporate significantly to avoid the formation of Bi-deficient phases. However, some deposited BiBr₃ can re-evaporate when the substrate temperature reaches and exceeds ≈65° C. Thus, there could be a competition between these two processes that determine the PLQY. At low temperatures, the precursors may not have reacted completely. At high temperatures, or if the temperature is increased too rapidly before BiBr₃ is locked in as Cs₂AgBiBr₆, BiBr₃ may evaporate, leading to Bi deficient phases in the films.

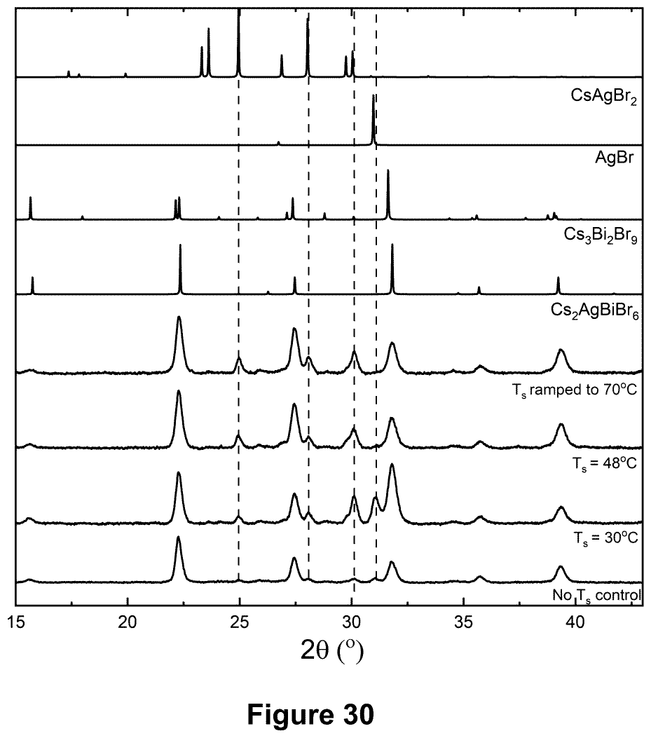

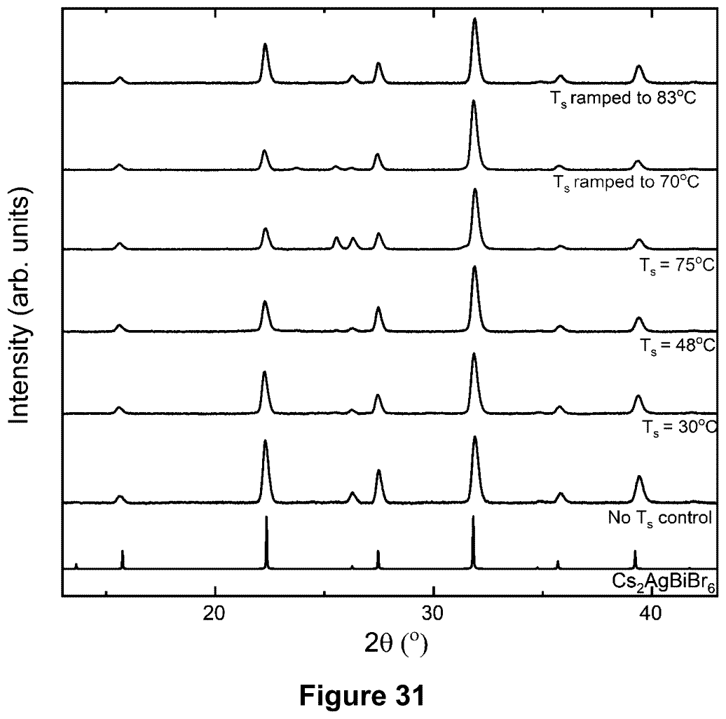

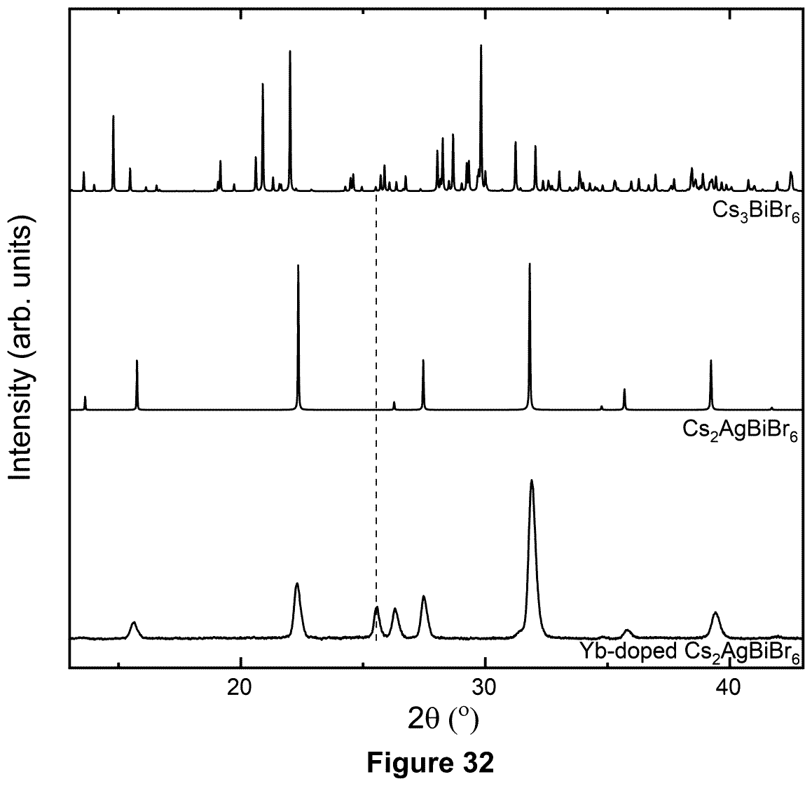

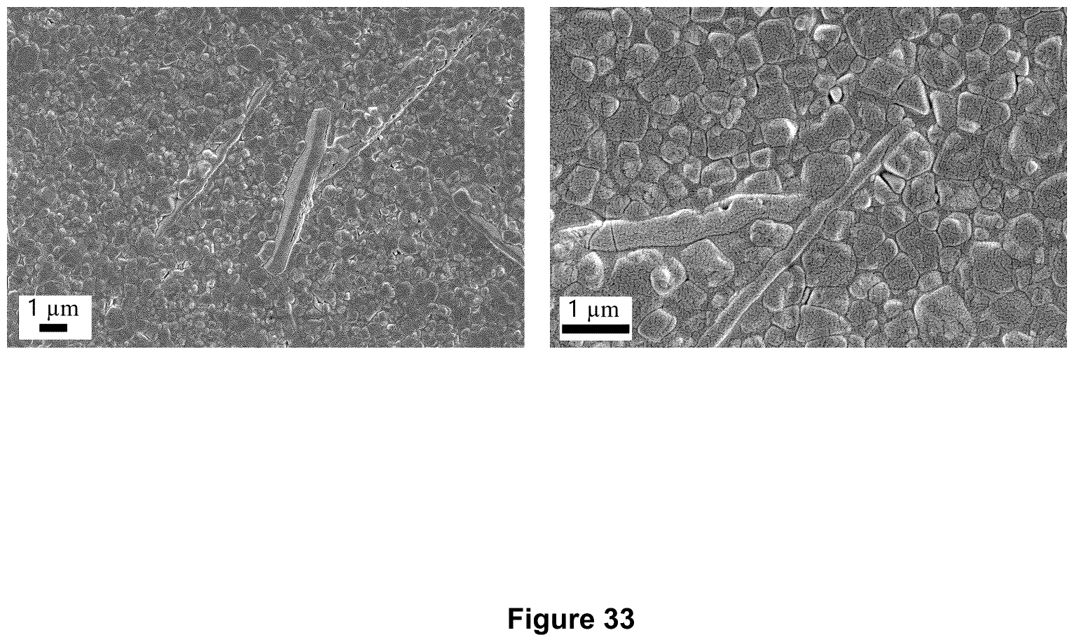

The reaction that forms Cs₂AgBiBr₆ appears to proceed at temperatures as low as 30° C. but is not complete. The XRD from the as-deposited films at 30° C. show all the expected Cs₂AgBiBr₆ diffraction peaks (FIG. 30). However, XRD also shows the presence of AgBr and CsAgBr₂, which indicates that not all BiBr₃ has reacted. In fact, the XRD patterns from the as-deposited films all show the presence of AgBr and CsAgBr₂ regardless of the deposition temperature, whether maintained constant throughout the deposition or ramped during CsBr deposition. Thus, some BiBr₃ remains unreacted at all temperatures and may evaporate above 65° C. during deposition or annealing. This BiBr₃ loss may lead to the formation of Bi-deficient phases such as Cs₃BiBr₆ during annealing. Indeed, XRD of the deposited films while keeping substrate temperature constant at 75° C. show Bi-deficient phases (FIG. 31). Specifically, the XRD peak at 25.6° is attributed to Cs₃BiBr₆, a commonly observed impurity phase when films are BiBr₃ deficient (FIG. 32). This indicates that significant amounts of BiBr₃ must have re-evaporated at 75° C. SEM images show these impurity phases as long rods (1-10 μm, see FIG. 33), and EDS analysis shows that their elemental composition is close to that expected for Cs₃BiBr₆ (FIG. 33). These Bi-deficient phases also absorb UV and blue light, but their PLQY is much lower, thus lowering the NIR PLQY of the films. In addition, their presence can also lead to nonradiative pathways such as recombination on defects at the grain boundaries between the desired and impurity phases. These nonradiative processes can compete with the energy transfer between the perovskite host and Yb³⁺, thus lowering the NIR PLQY.

When the substrate temperature is ramped up slowly during CsBr deposition, the reaction rate between the CsAgBr and BiBr₃ increases, and as they react to form Cs₂AgBiBr₆ film, BiBr₃ is prevented from leaving. However, the impurity XRD peak at 25.6° is still present (FIG. 31) in the film deposited with the substrate temperature ramped to 70° C. during CsBr deposition. The peak is weak, suggesting the impurity is only present in a small amount. The XRD peak at 25.6° is not present in the film deposited with the substrate temperature ramped to 83° C. during CsBr deposition. Thus, only small amounts of Cs₃BiBr₆ form in these films deposited in the ramping temperature mode. This suggests that ramping the temperature reduces the BiBr₃ loss from the films.

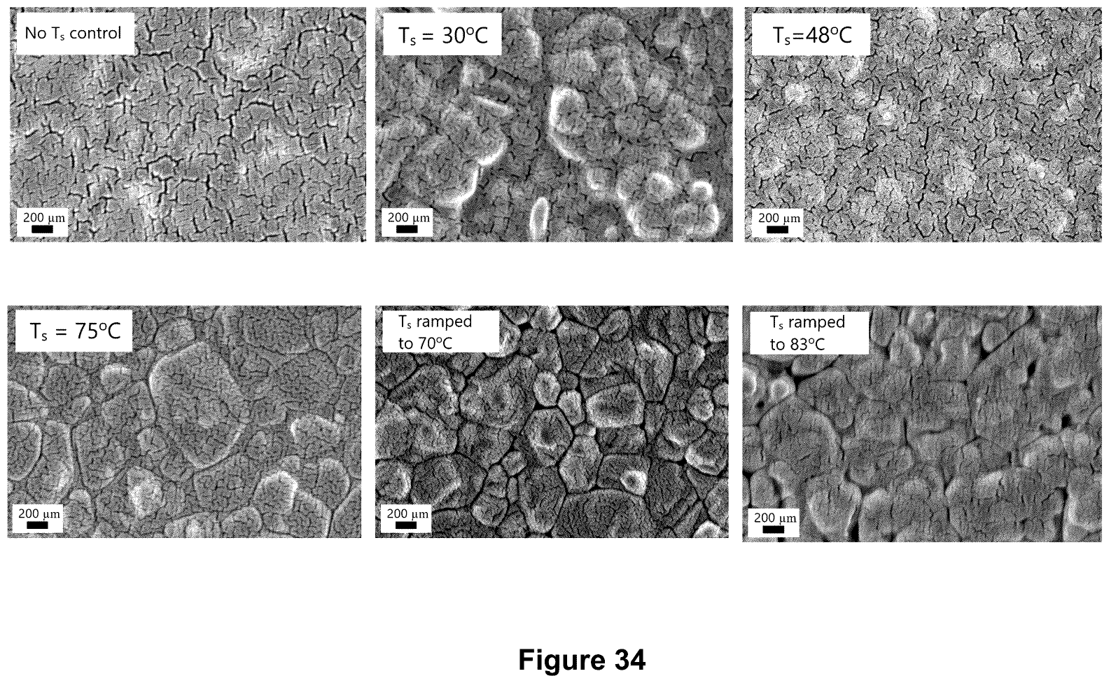

SEM images of Cs₂AgBiBr₆ films doped with 8% Yb show grain-like features with fissures (FIG. 34). These grain-like features are not well defined in films deposited in the no-temperature-control and the constant-temperature (30 and 48° C.) modes, i.e., at the lower temperature range investigated. When the films are deposited at higher temperatures, 75° C., or while ramping the temperature to 70 and 83° C. during CsBr evaporation, the films consist of larger grain sizes (300-500 nm). These large grains show fissures that separate 50-100 nm smaller grain-like domains. The fissures are a result of film densification during annealing. However, the theoretical film contraction factor, δ, defined as the ratio of the sum of the individual unreacted precursor compound thicknesses to the thickness of the target material after the complete reaction, is 0.99. This calculation assumes a stoichiometric reaction and could be lower if, for instance, some BiBr₃ leaves the film during the reaction. Thus, the appearance of the fissures supports that some BiBr₃ leaves the film during the deposition and annealing.

Seeing differences in morphology between the films in FIG. 34 is surprising because all films are annealed at the same temperature, 300° C., much higher than the deposition temperature. Therefore, one would expect the morphology to develop during the annealing and all films to be similar. However, this is not the case, indicating how the film forms during deposition at low temperatures (<83° C.) affect how the film morphology develops during annealing (at 300° C.). This is consistent with BiBr₃ leaving the film during deposition and partial reaction completion during deposition. The remaining AgBr, CsAgBr₂, and BiBr₃ (FIG. 30) react during annealing, which may lead to different morphologies depending on the amount of BiBr₃ in the film after deposition. Curiously, the morphology does not appear to affect PLQY strongly, as films with different morphologies, e.g., films deposited at 75° C. (FIG. 34) and films deposited without temperature control (≈30° C.) or at 30° C. have nearly the same PLQY.

### Effect of BiBr₃ Evaporation Rate on PLQY

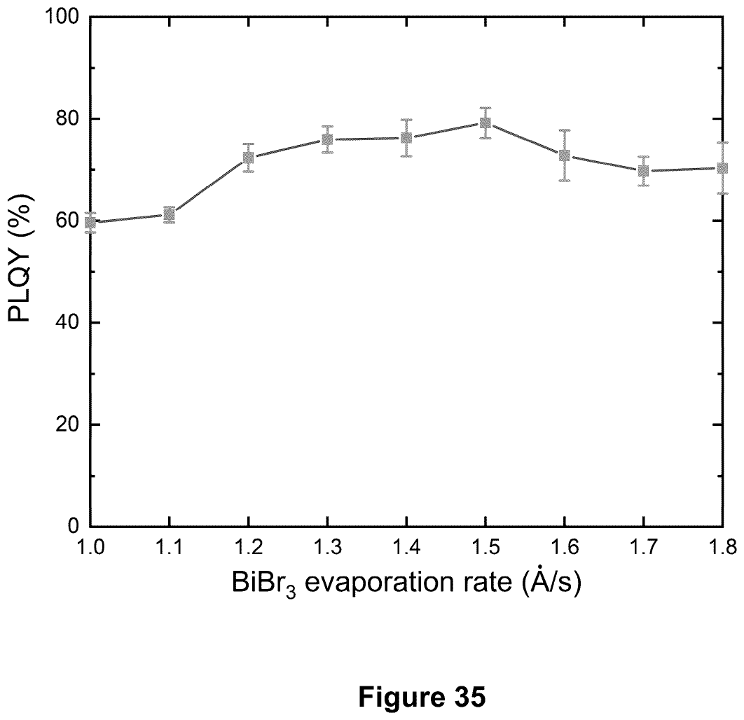

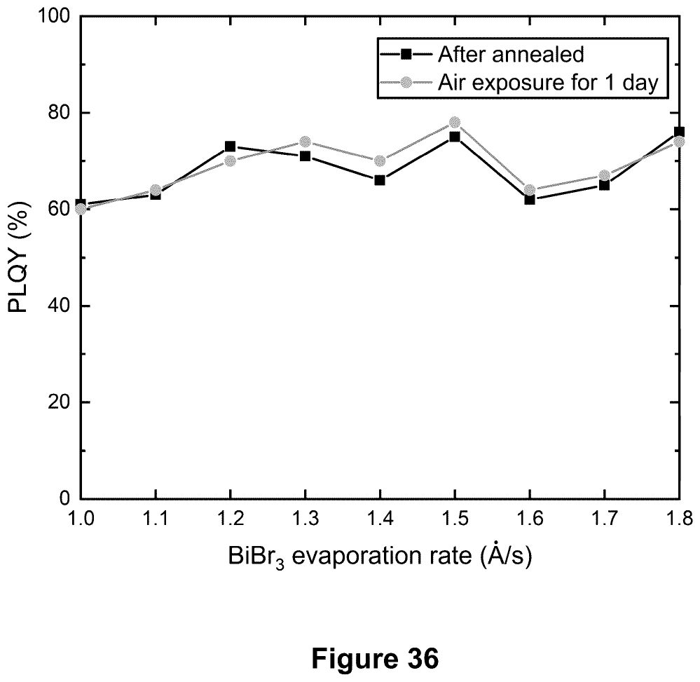

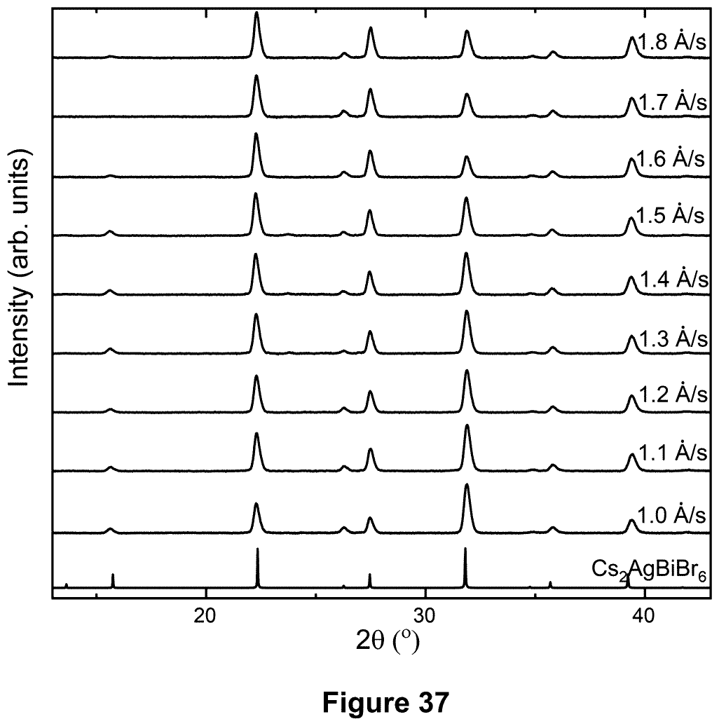

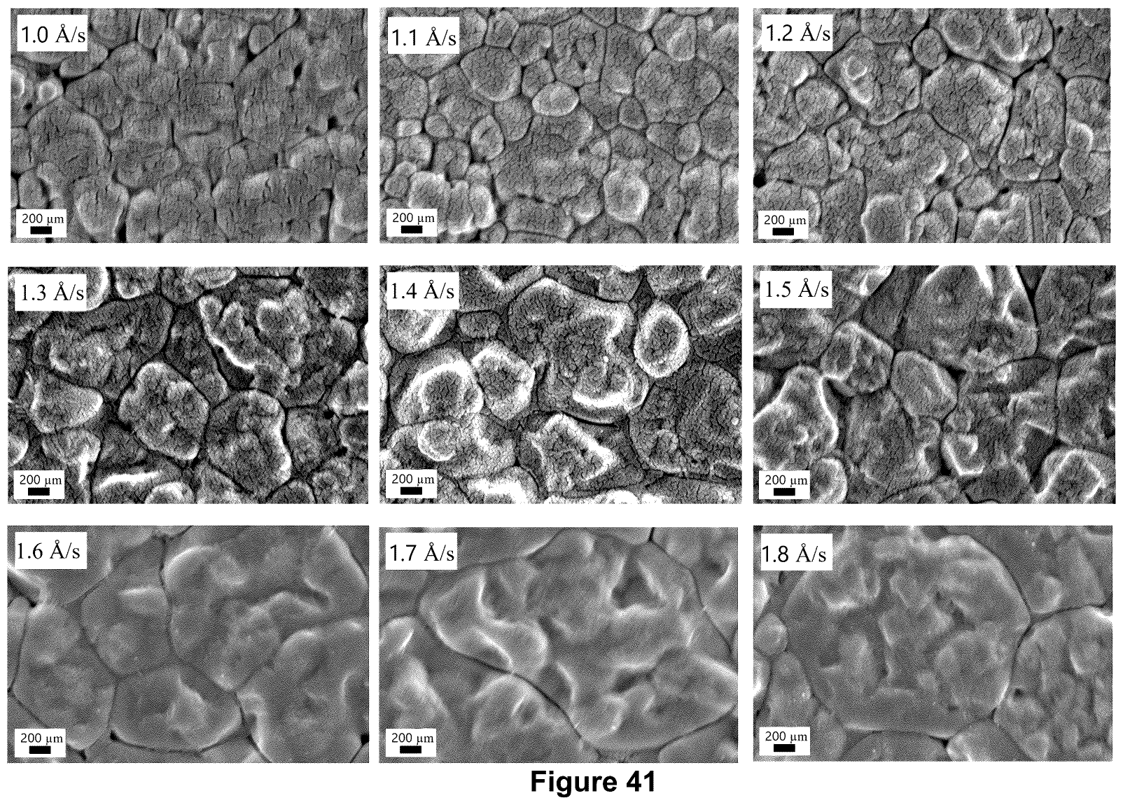

Based on the dependence of PLQY on how the substrate temperature changes during deposition, the PLQY is correlated with the amount of Bi incorporated into the film. A series of depositions was conducted to test this hypothesis while increasing the BiBr₃ evaporation rate from 1.0 to 1.8 Å/s, with 1.0 Å/s corresponding to stoichiometric Cs₂AgBiBr₆. All films were deposited while ramping the substrate temperature to 83° C. during CsBr evaporation, and Yb doping was kept constant at 8%. FIG. 35 and FIG. 36 show the PLQY and XRD of films synthesized with different BiBr₃ evaporation rates. After the films are removed from the glovebox and exposed to air, PLQY initially increases (less than 5%) but remains stable after a few days in the air for up to 30 days (FIG. 35 and FIG. 36). The PLQY improves from 61 to 78% as the BiBr₃ rate increases from 1.0 to 1.5 Å/s, suggesting that the excess BiBr₃ compensates for the BiBr₃ leaving and reduces the formation of impurity phases. XRD spectra of these films match with the reference pattern of Cs₂AgBiBr₆ and do not show the impurity peak at 25.6° (FIG. 37). PLQY starts decreasing when the BiBr₃ rate exceeds 1.5 Å/s. Some Bi³⁺ deficiency is needed to accommodate the Yb³⁺ ion substitution into the BiBr₆³⁻ octahedra. Excess Bi³⁺ ions compete with Yb³⁺ ions for the octahedral positions, so the amount of Yb³⁺ ions substitution may eventually decrease as more BiBr₃ is added to the film. The changes in the Bi³⁺ composition are small, but the film composition obtained from EDS measurements confirms the increase in bismuth concentration from 8.4% to 9.1%, with an evaporation rate from 1.0 to 1.8 Å/s (Table 3). SEM images in FIG. 41 show that the grain sizes increases and fissures disappear with increasing BiBr₃ flux to the surface. This confirms that the fissures in FIG. 34 are related to the BiBr₃ loss from the film.

TABLE 3
EDS data of a Cs₂AgBiBr₆ film doped with 8% Yb and deposited
in the ramping-temperature mode as the substrate temperature
was increased from 30° C. to 83° C. during CsBr
evaporation. The stoichiometric composition is 20% Cs,
10% Ag, 10% Bi, 60% Br without taking into account the
Yb, which is 8% of the octahedral Bi positions or 0.8%.

| BiBr₃ Evaporation Rate | Composition | | | | |
|---|---|---|---|---|---|
| (Å/s) | % Cs | % Ag | % Bi | % Br | % Yb |
| 1.0 | 18.1 | 9.4 | 8.4 | 63.8 | 0.3 |
| 1.1 | 18.7 | 9.7 | 8.5 | 62.8 | 0.2 |
| 1.2 | 18.2 | 9.6 | 8.5 | 63.4 | 0.3 |
| 1.3 | 18.0 | 9.8 | 8.5 | 63.1 | 0.6 |
| 1.4 | 18.1 | 9.8 | 8.5 | 62.9 | 0.7 |
| 1.5 | 17.8 | 9.8 | 8.6 | 63.4 | 0.4 |
| 1.6 | 18.9 | 10.5 | 8.7 | 61.4 | 0.6 |
| 1.7 | 19.0 | 10.0 | 8.9 | 62.0 | 0.3 |
| 1.8 | 18.8 | 10.2 | 9.1 | 61.3 | 0.6 |

### Excitation Dependence of PLQY

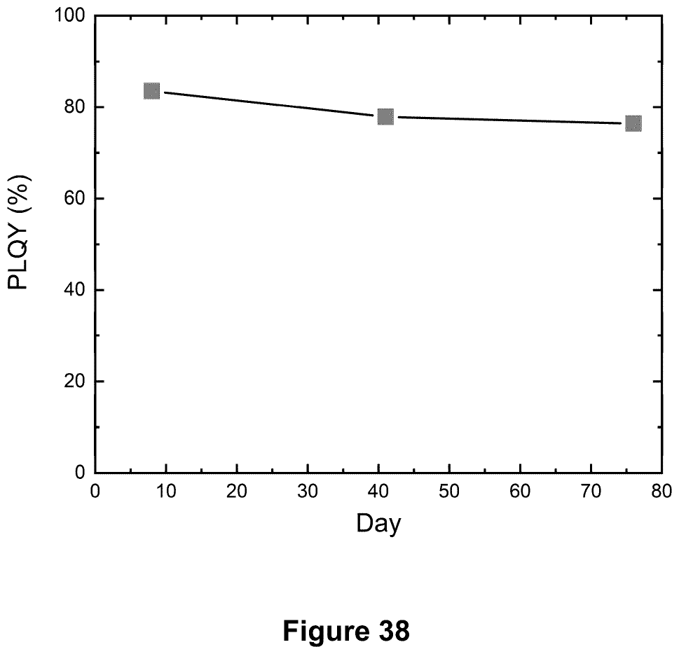

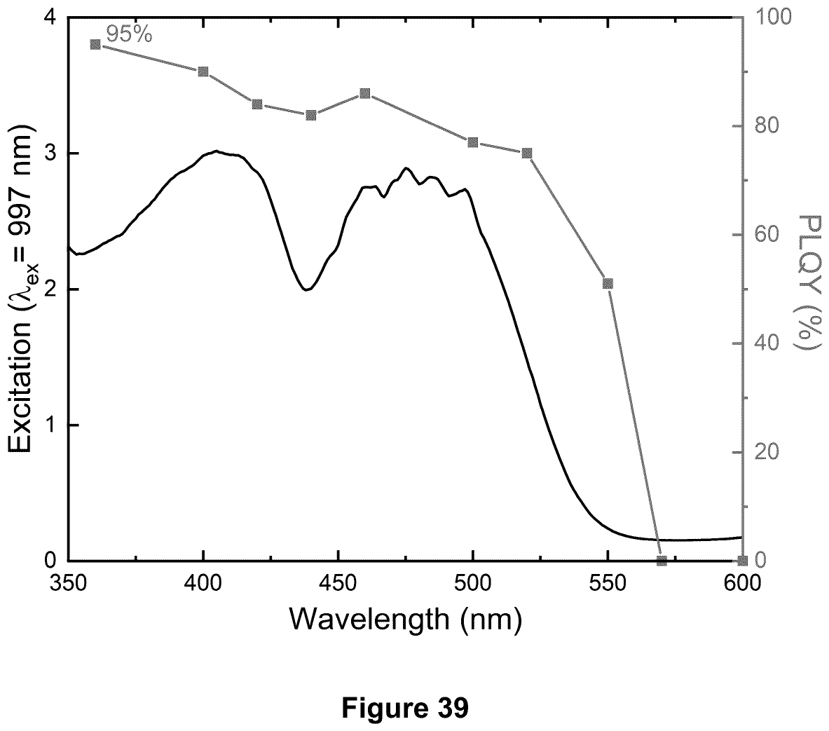

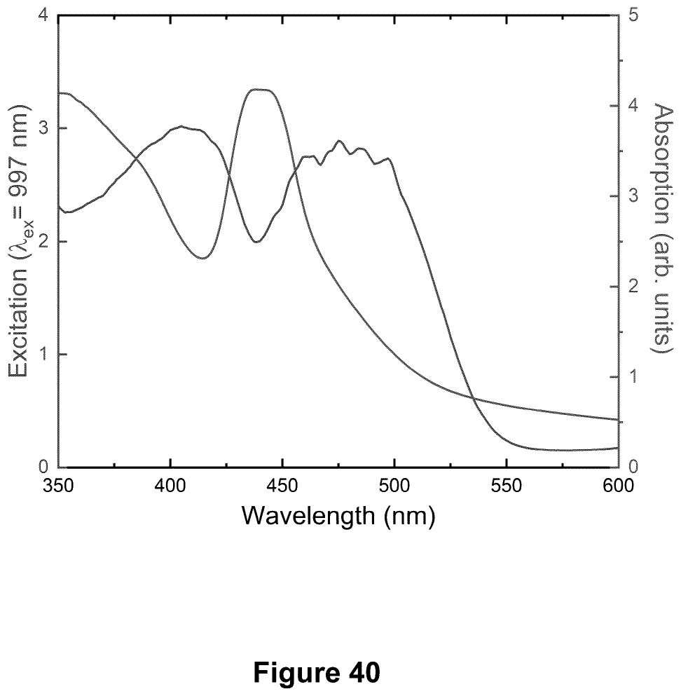

The dependence of PLQY on the excitation wavelength for a film synthesized at an optimized BiBr₃ evaporation rate was examined. The highest PLQY measured under 420 nm excitation is 84% and increases to 95% when the film is excited under 360 nm. The films retain 91% of their initial PLQY values after two months (FIG. 38). FIG. 39 shows the excitation spectrum and the PLQY dependence on the excitation wavelength of this film after 1 month. When the excitation energy is less than the Cs₂AgBiBr₆ bandgap (˜560 nm, ˜2.2 eV), PLQY is 0%, indicating the perovskite host sensitizes the Yb³⁺ ions. PLQY values are above 75% when the excitation wavelength is between 360 and 520 nm (2.4 eV). That PLQY is still >60% at 2.4 eV, less than twice the Yb^{3+ 2}F_{5/2}→²F_{7/2} electronic transition (2. 5 eV) suggests that at least some of the perovskite-Yb³⁺ energy transfer is not by quantum cutting. The dip at 440 nm in the excitation spectrum matches the absorption exciton peak in FIG. 40, which suggests Yb³⁺ ions receive energy from the perovskite host when the Cs₂AgBiBr₆ excited electrons relax from the conduction band edge to the valence band.

Yb-doped Cs₂AgBiBr₆ thin films have been synthesized by sequential vapor deposition, and the dependence of its NIR emission on substrate temperature and BiBr₃ evaporation rate was examined. PLQY of Yb-doped Cs₂AgBiBr₆ thin films depends strongly on the substrate temperature during the deposition and the BiBr₃ evaporation rates. Three temperature modes were studied: no-temperature-control, constant-temperature, and ramping-temperature modes. Films synthesized using the ramping-temperature mode yielded the highest PLQY. The ramping-temperature mode allows precursors to react to lock in the volatile precursor BiBr₃ as Cs₂AgBiBr₆ and prevent its re-evaporation. Evaporation of BiBr₃ leads to bismuth-deficient phases such as Cs₃BiBr₆, which introduces nonradiative relaxation pathways that compete with the energy transfer between the host Cs₂AgBiBr₆ and Yb³⁺ ions. The BiBr₃ evaporation rate was optimized to reduce the impurity formation, resulting in a PLQY of 95%. The film is stable under ambient conditions and retains 91% of its PLQY after one month.

### Experimental Section

### Thin-Film Deposition

Films were deposited in a glove-boxed physical vapor deposition system (Angstrom Engineering). CsBr (99.9%, Acros Organics), AgBr (99.9%, Beantown Chemical), and YbBr₃ (hydrate, 99.99%, Alfa Aesar) were loaded into separate alumina crucibles and baked overnight at 100, 100, and 110° C., respectively. BiBr₃ (99%, Alfa Aesar) was loaded into a quartz crucible and baked at 60° C. overnight. The glass substrates (25×25 mm², Thin Film Devices) were sonicated in a 1:1 solution by volume of acetone (ACS Grade, VWR) and isopropanol (99.5%, VWR) for 30 minutes, dried in an oven, and cleaned with O₂ plasma for 30 minutes using Expanded Plasma Cleaner PDC-001-HP (Harrick Plasma). Each precursor's evaporation rate was monitored by separate quartz crystal microbalances (QCMs). The tooling factors were determined and reported previously (Gloeckler, M. Sites, J. R. J. Phys. Chem. Solids. 2005, 66, 1891-1894).

To synthesize Cs₂AgBiBr₆ films doped with 8% Yb, BiBr₃, YbBr₃, and AgBr were co-deposited on glass substrates first, followed by CsBr. (Yb content is reported in percent of the Bi lattice positions in the Cs₂AgBiBr₆ structure.) During all depositions, YbBr₃ and AgBr evaporation rates were maintained at 0.08 Å/s and 0.37 Å/s, respectively. The effect of BiBr₃ flux was explored by varying the evaporation rate from 1.00 to 1.80/s, with 1.0 Å/s being the stoichiometric value for 8% Yb-doped Cs₂AgBiBr₆ and 1.1-1.8 Å/s corresponding to 10-80% excess BiBr₃. The CsBr evaporation rate was 1.21 Å/s. The CsBr, YbBr₃, and AgBr source temperatures were manipulated to control the evaporation rates but were approximately 550, 620, and 600° C., respectively. The BiBr₃ source temperature varied from 110 to 150° C., depending on the evaporation rate and the starting amount of BiBr₃ in the crucible. The effects of substrate temperature were examined in three modes: (1) without substrate temperature control (hereafter referred to as the no-temperature-control mode), (2) with substrate temperature maintained constant at a set value (hereafter referred to as the constant-temperature mode), and (3) with ramping the substrate temperature (hereafter referred to as the ramping-temperature mode). The heater was disabled for the no-temperature-control mode, and the substrates were heated naturally with the heat from thermal sources and evaporated materials. The substrates were kept at a constant temperature (30, 48, or 75° C.) throughout the depositions in the constant-temperature mode. For ramping temperature mode, the temperature was kept at 30° C. for the first layer (BiBr₃, AgBr, and YbBr₃) and then ramped slowly to either 70 or 83° C. during the second layer (CsBr) deposition. The substrates were cooled to 30° C. immediately after the deposition. The system's base pressure was 4×10⁻⁷ Torr, while the chamber pressure rose to ≈10⁻⁶ Torr during the deposition. Each layer was deposited for 30 minutes, resulting in 490±10 nm thick Yb-doped Cs₂AgBiBr₆ films. The films were annealed on a hot plate in the glovebox under nitrogen at 300° C. for one hour.

X-ray diffraction, scanning electron microscopy, UV-visible absorption spectroscopy, and PLQY measurements were conducted in the same manner as previously published (Tran, M. N. et al., J. Mater. Chem. A. 2021, 9, 13026-13035). NIR PL was excited at 420 nm for all films unless noted otherwise. In addition, the excitation wavelength dependence of the PLQY from the highest performing film was examined by varying the excitation between 360 to 600 nm.

### Film Volume Shrinkage/Expansion Factor Calculations

When CsBr, AgBr, and BiBr₃ react to form Cs₂AgBiBr₆, the film will shrink because of the differences in the densities of these compounds. The shrinkage factor, δ, is defined as the ratio of the sum of the individual unreacted precursor compound (i.e., CsBr, AgBr, and BiBr₃) thicknesses to the thickness of the target material, Cs₂AgBiBr₆, after they have reacted completely via the reaction

$$2 CsBr + AgBr + {BiBr}_{3} \to {Cs}_{2} {AgBiBr}_{6} .$$

The shrinkage factor is given by

$$δ = \frac{\sum {R}_{j}}{{R}_{product}} = \frac{\sum {v}_{j} \frac{{M}_{j}}{{ρ}_{j}}}{{v}_{product} \frac{{M}_{product}}{{ρ}_{product}}}$$

where the sum is over all the precursor compound (i.e., CsBr, AgBr, and BiBr₃) deposition rates, Rⱼ, and R_{product} is the product film deposition rate. This factor depends only on the stoichiometric coefficients, ν, densities, ρ and molecular weights, M, of the precursors and products. Using the values in Table 4, δ=0.99.

TABLE 4
Table of densities and molecular weights
for the precursors and the product.

| Compound | Density (g/cm3) | Molecular Weight(g/mole) |
|---|---|---|
| AgBr | 6.473 | 187.77 |
| BiBr₃ | 4.44 | 448.69 |
| CsBr | 4.43 | 212.81 |
| Cs₂AgBiBr₆ | 4.65 | 1062.08 |

### Example 3: Strong Near-Infrared Emissions from Yb-Doped Cs₂AgBiCl₄Br₂ Thin Films

The double perovskite Cs₂AgBiCl_{6-y}Br_{y} bandgap can be tuned by varying y (0≤y≤6). The bandgap determines the perovskite absorption, hence determining the light wavelength range is converted to NIR emission via downconversion. In this example, Yb is doped into in Cs₂AgBiCl₄Br₂ thin films, which has a bandgap of 2.5 eV. The optimized synthesis conditions for Yb-doped Cs₂AgBiBr₆ thin films are used as the starting point and the experiments were designed to explore the dependence of PLQY on deposition and annealing conditions for Yb-doped Cs₂AgBiCl₄Br₂ thin films.

Crystal Structures and Optical Properties of Yb-Doped Cs₂AgBiCl₄Br₂ Films

Cs₂AgBiCl₄Br₂ films doped were deposited with 8% Yb using stoichiometric and 50% excess BiCl₃. Co-evaporation and sequential deposition was used for 8% Yb—Cs₂AgBiCl₄Br₂ films and the substrate temperature was ramped during the deposition.

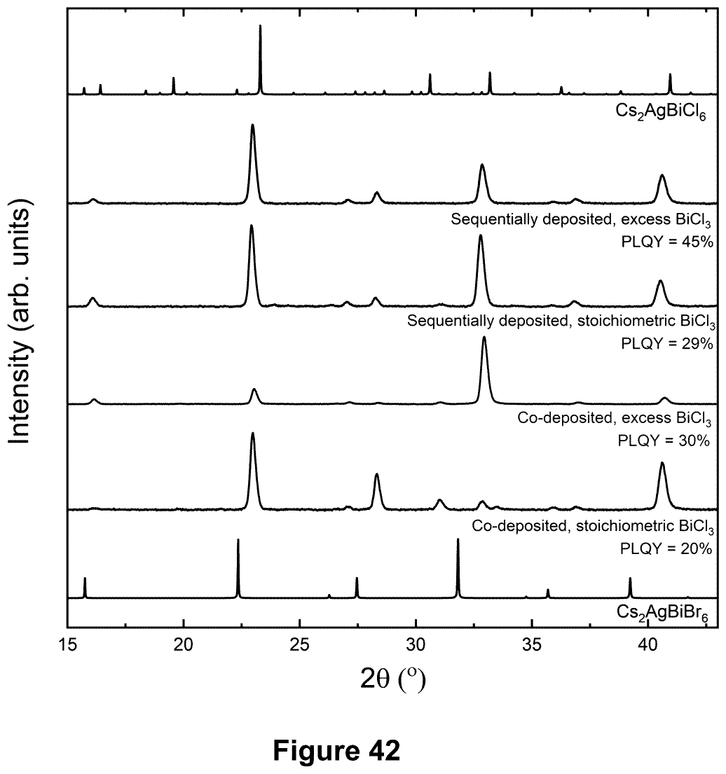

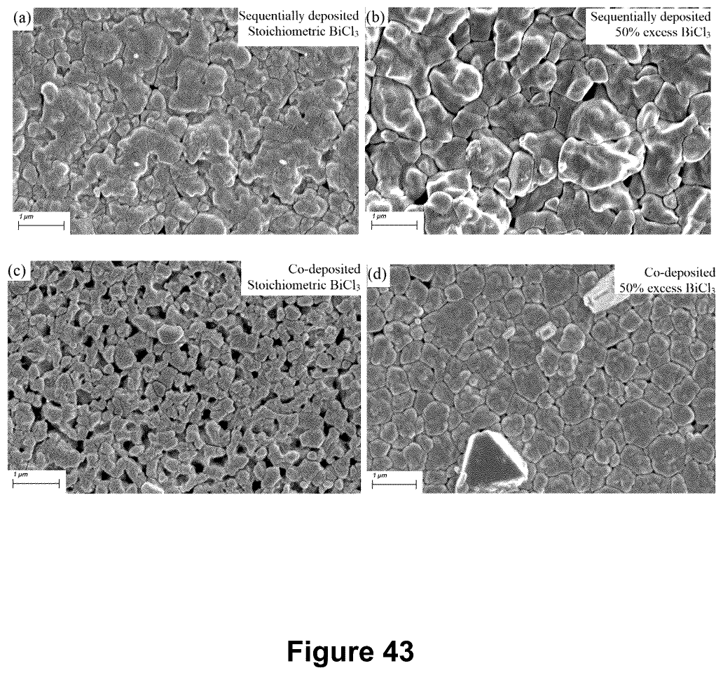

XRD patterns show that all Cs₂AgBiCl₄Br₂ films doped with 8% Yb and deposited with stoichiometric and excess BiCl₃ form the target cubic structure (#225, Fm3̅m) (FIG. 42). XRD peaks of Yb-doped Cs₂AgBiCl₄Br₂ films are shifted compared to the corresponding XRD peaks of Cs₂AgBiCl₆ and Cs₂AgBiBr₆, and a single peak is observed at each expected diffraction suggesting that Cl⁻ and Br⁻ ions are well mixed throughout the films. The same XRD shift has been observed in Cs₂AgBiCl₄Br₂ powders. A lattice constant of 11.06 Å can be extracted for Yb-doped Cs₂AgBiCl₄Br₂ films, which is within ±1% of the reported value in literatures (Gray, M. B. et al, J. Mater. Chem. C. 2019, 7 (31), 9686-9689; and Dakshinamurthy, A. C. et al, J. Phys. Chem. C. 2022, 127 (3), 1588-1597). No impurity or phase segregation is detected from XRD data, suggesting Yb is doped successfully into Cs₂AgBiCl₄Br₂ structure. SEM images show that most of the films are made of uniform grains, which support the stability of Yb Cs₂AgBiCl₄Br₂ structure (FIG. 43). SEM images of stoichiometric, co-deposited 8% Yb-doped Cs₂AgBiCl₄Br₂ films show scattered crystallites with different appearance and morphology than the background film suggesting the presence of some impurity phases scattered on the film surface (FIG. 43). Composition analysis from EDS of these impurity phases suggests that they are Bi-deficient phases: they contain 7.6% Bi compared to the concentration expected from a stoichiometric film, 10%. Bi deficiency is expected since BiCl₃ starts evaporating at 70° C., which is slightly higher than BiBr₃ but still lower than the substrate temperature. EDS measurements from the homogeneous areas of all the films show the expected Cs₂AgBiCl₄Br₂ stoichiometry (Table 5). There is also no significant increase in Bi concentration in films deposited with excess BiCl₃. The excess BiCl₃ leaves the film during the substrate heating and annealing.

TABLE 5
Composition of an 8% Yb-doped Cs₂AgBiCl₄Br₂ film
deposited with stoichiometric or 50% excess BiCl₃.

| | Composition | | | | | |
|---|---|---|---|---|---|---|
| Film | % Cs | % Ag | % Bi | % Cl | % Br | % Yb |
| Expected stoichiometric | 19.4 | 9.7 | 9.7 | 41.0 | 19.4 | 0.8 |
| 8% Yb-doped Cs₂AgBiCl₄Br₂ | | | | | | |
| Sequential deposited with | 21.8 | 10.4 | 9.9 | 39.5 | 17.6 | 0.8 |
| 50% excess BiCl₃ | | | | | | |
| Sequential deposited with | 21.8 | 11.7 | 9.3 | 37.7 | 19.0 | 0.5 |
| stoichiometric BiCl₃ | | | | | | |
| Co-deposited with 50% | 20.7 | 10.8 | 9.1 | 39.1 | 19.3 | 1.0 |
| excess BiCl₃ | | | | | | |
| Co-deposited with | 20.5 | 10.7 | 9.2 | 39.7 | 16.1 | 1.0 |
| stoichiometric BiCl₃ | | | | | | |

Co-evaporated and sequentially deposited Yb-doped Cs₂AgBiCl₄Br₂ films with excess BiCl₃ exhibit higher PLQY than those deposited using stoichiometric BiCl₃ (FIG. 42). This is consistent with BiCl₃ leaving the films during deposition, which leads to the formations of Bi-deficient phase impurity that decreases NIR emission. Sequentially deposited films show higher PLQY than co-deposited films, suggesting that the reaction among precursors are different for two synthesis schemes. One explanation is that Yb³⁺ ions substitute into the crystal structures more efficiently in the sequential deposition, which leads to higher PLQY The highest PLQY, 45%, was obtained from 8% Yb-doped Cs₂AgBiCl₄Br₂ thin film, which is sequentially deposited with excess BiCl₃.

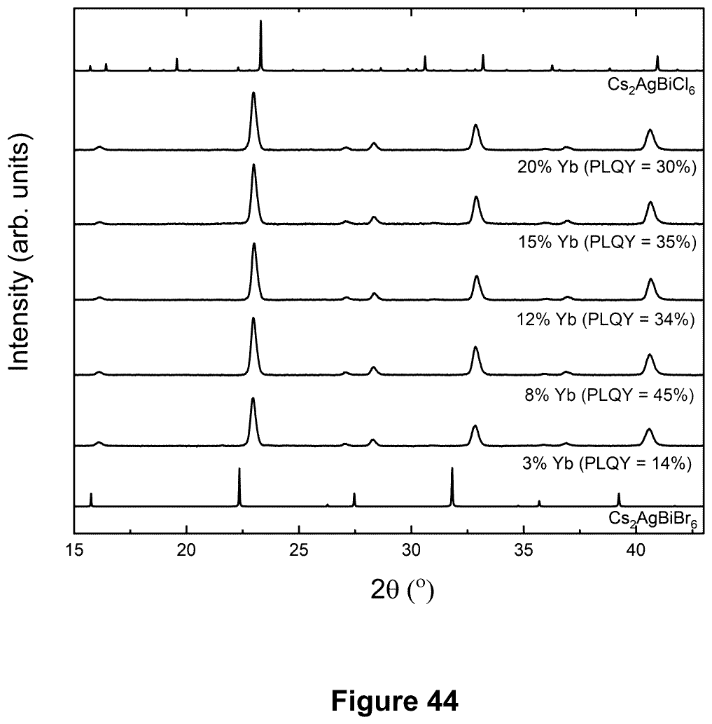

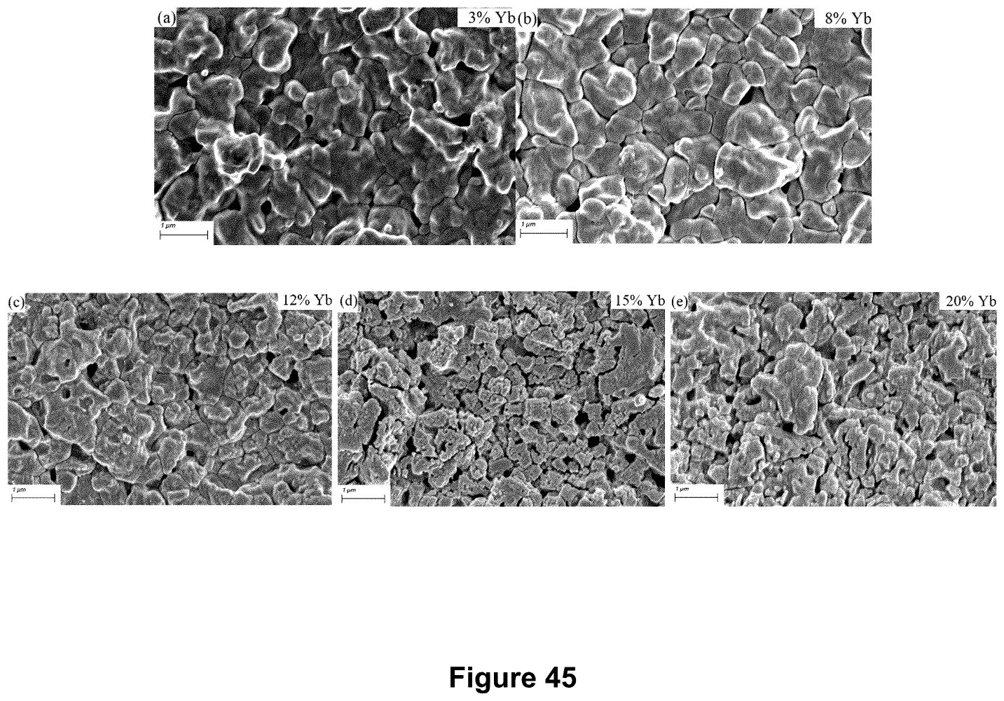

Next, using the sequential deposition scheme with excess BiCl₃, Yb concentration was varied from 3 to 20% to study the effects of Yb % doping on PLQY XRD patterns show that all films crystallize with the target cubic structure Fm3̅m (FIG. 44). No phase segregation and impurity phases were detected from XRD patterns. There is no clear XRD peak shift when Yb concentration increases. SEM images show phase-pure, homogeneous films for all Yb concentration (FIG. 45). Films with 3% and 8% Yb show large and uniform grain size, approximately about 1 μm. Films with higher Yb concentrations contain more voids and smaller and non-uniform grain sizes, about 200 nm.

PLQY is highest for film doped with 8% Yb, which is the same optimal Yb concentration for Yb-doped Cs₂AgBiBr₆ films. PLQY decreases sharply from 45% to 14% when Yb concentration decreases from 8% to 3%, suggesting that not enough Yb³⁺ ions are doped into the crystal structure for NIR emission. Increasing Yb concentration to above 8% also reduces PLQY, possibly due to quenching effect, in which the excitation energy transfers from one Yb³⁺ to another and eventually to a defect where a nonradiative process quenches it.

In conclusion, the mix halide perovskite host Cs₂AgBiCl₄Br₂ transfers energy efficiently to Yb, which leads to strong NIR emissions with quantum yield of 45%.

### Experimental Details

### Thin-Film Deposition

Films were deposited in a glove-boxed physical vapor deposition system (Angstrom Engineering). The glass substrates (15×15 mm², Thin Film Devices) were sonicated in a 1:1 solution by volume of acetone (ACS Grade, VWR) and isopropanol (99.5%, VWR) for 30 minutes, dried in an oven, and cleaned with O₂ plasma for 30 minutes using Expanded Plasma Cleaner PDC-001-HP (Harrick Plasma). Each precursor's evaporation rate was monitored by separate quartz crystal microbalances (QCMs). During the deposition of Yb-doped Cs₂AgBiCl₄Br₂ films, precursors were either co-evaporated or sequentially deposited. For co-evaporation, four precursors, BiCl₃ (99.9%, Alfa Aesar), AgCl (99.995%, Beantown Chemical), YbCl₃ (hydrate, 99.9%, Alfa Aesar), and CsBr (99.9%, Acros Organics), were simultaneously deposited at 0.85, 0.33, 0.07, and 1.21 Å/s, respectively. These evaporation rates correspond to stoichiometric Cs₂AgBiCl₄Br₂ doped with 8% Yb. The BiCl₃ flux was increased to 1.3 Å/s, corresponding to 50% excess BiCl₃. The substrate temperature was ramped from 30° C. to 83° C. during the deposition, which lasted 30 minutes.

For sequential deposition, three of the four precursors, BiCl₃, AgCl, and YbCl₃, were co-deposited on glass substrates, followed by CsBr deposition on top of this BiCl₃—AgCl—YbCl₃ layer. The substrate temperature was kept at 30° C. during the first layer deposition but ramped to 83° C. during the second layer deposition. BiCl₃ and AgCl evaporation rates were kept constant at 1.3 Å/s (excess 50% BiCl₃) and 0.33 Å/s, respectively, while the YbCl₃ evaporation rate varied from 0.04 to 0.17 Å/s. The CsBr evaporation rate was 1.21 Å/s. stoichiometric Cs₂AgBiCl₄Br₂ films doped with 8% Yb were deposited using sequential deposition, where the BiCl₃ evaporation rate was 0.85 Å/s. Each layer was deposited for 30 minutes. All films were annealed under nitrogen at 300° C. for 1 hour.

X-ray diffraction, scanning electron microscopy, UV-visible absorption spectroscopy, and PLQY measurements were conducted in the same manner as demonstrated in example 1 and 2.

### Example 4: Physical Vapor Deposition of Yb-Doped Cs₂AgBiBr₆ Thin Films from Ball-Milled Powders

Yb-doped Cs₂AgBiBr₆ thin films can be formed via co-evaporating Yb-doped Cs₂AgBiBr₆ powders and YbBr₃. The powders were mechanochemically prepared via ball milling. Ball mill is a low-cost technique that can create high quality, homogeneous powders, which can be used in combination with physical vapor deposition to form thin films. In this example phase pure Yb-doped Cs₂AgBiBr₆ powders are synthesized with quantum yield up to 51%, and the powders were co-evaporated with YbBr₃ to yield thin films that also exhibits strong near-infrared emission.

Yb-Doped Cs₂AgBiBr₆ Powders

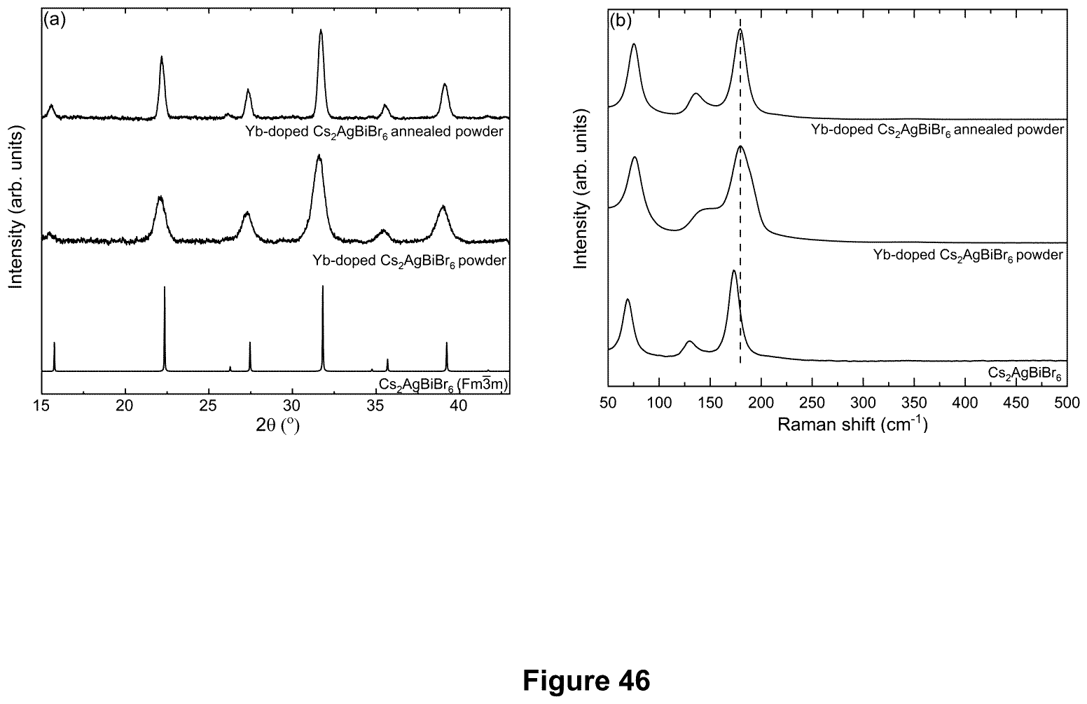

The mixture powders with the stoichiometric ratio of 8% Yb-doped Cs₂AgBiBr₆ was ball milled for four hours and form dark red powders. After annealing at 300° C. for 1 hour in the furnace, the powders turn light orange. X-ray diffraction and Raman spectra of the powders confirms the formation of Cs₂AgBiBr₆ cubic structure (#225, Fm3̅m) (FIG. 46 a, b). X-ray diffraction peaks of the annealed powders are sharp, well-defined (average FWHM=0.4°), and match well with the reference pattern simulated from the cubic Cs₂AgBiBr₆ structure. No extra XRD peaks were observed from common impurity phases such as Cs₃Bi₂Br₉, Cs₂AgBr₃ and AgBr. The sharp and well-matched XRD pattern suggests that the anneal powders consist of crystalline, phase pure Cs₂AgBiBr₆. Raman spectrum of the annealed powders exhibit the same pattern as undoped Cs₂AgBiBr₆ thin film, with three signature peaks at 75, 136 and 179 cm⁻¹. These peaks are assigned to the vibration modes T_{2g}, E_{g} and A_{1g} of the [BiBr₆]³⁻ and [AgBr₆]⁵⁻ octahedral, respectively. These peaks are shifted to higher wavenumbers compared to the undoped Cs₂AgBiBr₆ thin film (FIG. 46b), indicating the incorporation of Yb into the perovskite structure. Yb³⁺ replaces Bi³⁺ and Ag⁺ ions when doped in Cs₂AgBiBr₆, as shown in FIG. 2. Since Yb³⁺ ions have smaller radius than Bi³⁺ and Ag⁺ ions, the crystal structure is compressed with Yb doping, which shifts Raman peaks to higher wavenumbers.

The as-mixed Yb-doped Cs₂AgBiBr₆ powders also show XRD and Raman patterns that belong to Cs₂AgBiBr₆ structure, but the peaks are much broader than those of annealed powders (FIG. 46 a, b). This indicating that the as-mixed powders are less crystalline than the annealed ones, suggesting that post annealing is important to obtain high, quality crystalline powders.

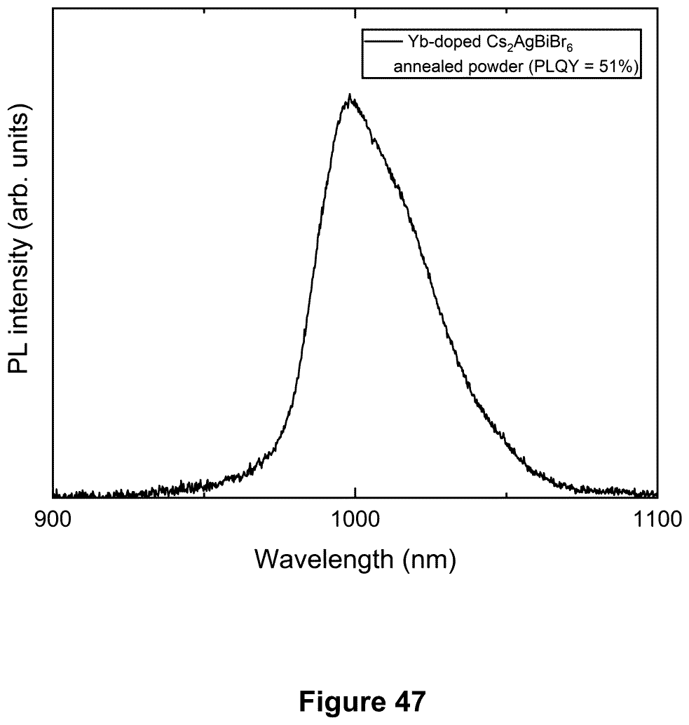

The annealed Yb-doped Cs₂AgBiBr₆ powders exhibit strong near-infrared emission when excited with ultraviolet light (λₑₓ=360 nm). The PL peak is centered at 998 nm (FWHM=41 nm), which is emitted via Yb³⁺ electronic transition ²F_{5/2}→²F_{7/2} (FIG. 47). The quantum yield of annealed powders is 51%, indicating efficient energy transfer between the perovskite host Cs₂AgBiBr₆ to Yb³⁺ ions and strong near-infrared emission from the activated Yb³⁺ ions.

Yb-Doped Cs₂AgBiBr₆ Thin Films

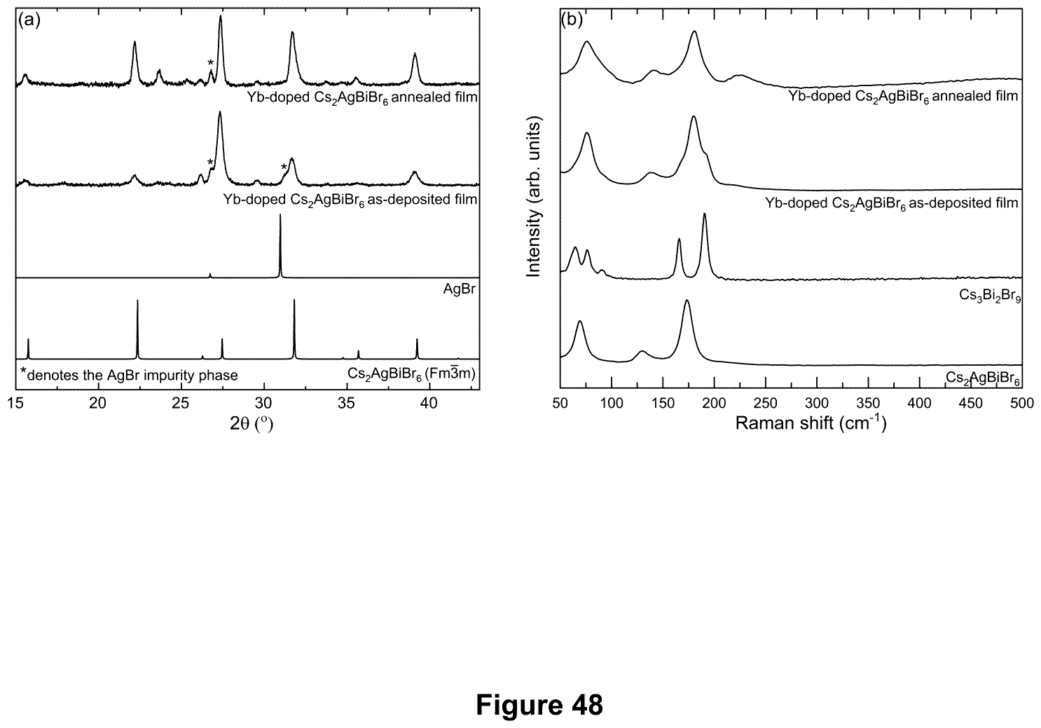

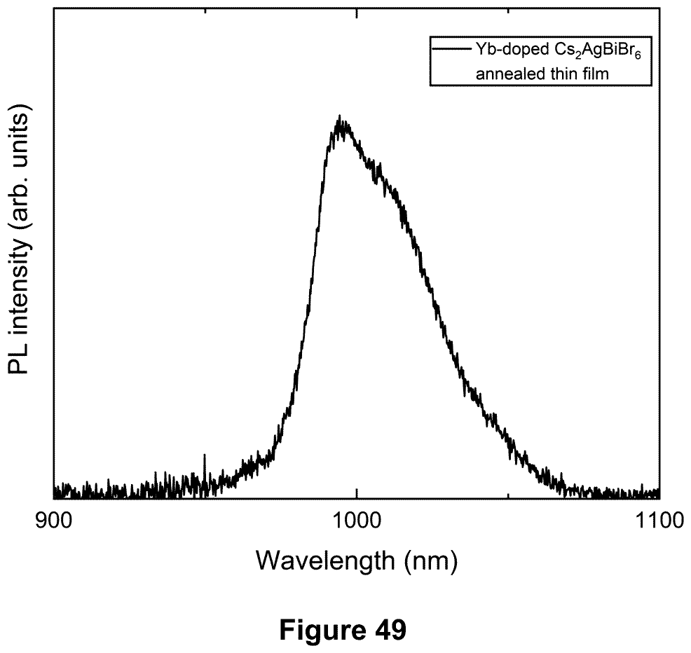

The annealed powders were evaporated simultaneously with YbBr₃ to yield Yb-doped Cs₂AgBiBr₆. The deposited film was annealed at 300° C. for one hour, which is the optimized annealing condition, as discussed in Example 1. Both as-deposited and annealed films show the XRD pattern corresponding to the Cs₂AgBiBr₆ target perovskite structure (FIG. 48a). The as-deposited film contains some broad and asymmetric XRD peaks at 26.77 and 31.25°, which can be attributed to impurity phases AgBr. This suggest that while the majority of Cs₂AgBiBr₆ powders evaporated and form Cs₂AgBiBr₆ thin film, a small portion decomposes to AgBr and and other phase impurities at high evaporating temperatures. This is also observed by Pantaler, M. et al. MRS Advances. 2018 3, 1819-1823 and Fan, P. et al. Nanomaterials 2019, 9 (12), 1760. The impurity peak at 31.25° disappears for the annealed film while the peak at 26.77° becomes more resolved, which indicates that the impurity phases can react during annealing to form Cs₂AgBiBr₆. The Raman spectrum of the as-deposited film shows the three Cs₂AgBiBr₆ peaks at 180, 139 and 75 cm⁻¹ and a shoulder peak at 192 cm⁻¹, which can be matched with Cs₃Bi₂Br₉ (FIG. 48b). This shoulder peak is not present in the Raman spectrum of annealed film, which consists only signature Cs₂AgBiBr₆ peaks at 180, 140 and 75 cm⁻¹. Raman data agrees well with XRD patterns that a small amount of Cs₂AgBiBr₆ powders decomposes to AgBr and Cs₃Bi₂Br₉ at high evaporating temperatures, but the impurities react during annealing to form Cs₂AgBiBr₆. These Raman peaks are also shifted to higher wavenumbers compared to undoped film, suggesting the incorporation of Yb into the perovskite crystal structure. The annealed Yb-doped Cs₂AgBiBr₆ film shows strong near-infrared emission centered at 997 nm and the emission curve obtains the same shape as the annealed powder (FIG. 49).

### Experimental Details

### Powder Preparation

All precursors were baked under vacuum to remove moisture before ball milling. Four precursors include AgBr (0.5089 g, 99.9%, Beantown Chemical), CsBr (1.1721 g, 99.9%, Acros Organics), BiBr₃ (1.2190 g, 99%, Alfa Aesar) and YbBr₃ (0.1173 g, 99.99%, Alfa Aesar) were added to a 50 ml a zirconia milling jar. Zirconia balls of different sizes (50.5132 g in total) were also added to the jar. The powder mixture was ball milled using MSE Supplies Vertical High Energy Planetary Ball Mill inside a glovebox for 4 hours in alternating directions. Each direction was run for 30 minutes, rest for one minute and switched to the other direction. The rotation speed is about 700 RPM. After ball milling, the powders were transferred to an alumina boat and annealed inside a furnace (Thermolyne Benchtop Furnace) at 300° C. for 1 hour.

### Thin-Film Deposition

Films were deposited in a glove-boxed physical vapor deposition system (Angstrom Engineering). The glass substrates (25×25 mm², Thin Film Devices) were sonicated in a 1:1 solution by volume of acetone (ACS Grade, VWR) and isopropanol (99.5%, VWR) for 30 minutes, dried in an oven, and cleaned with O₂ plasma for 30 minutes using Expanded Plasma Cleaner PDC-001-HP (Harrick Plasma). The substrate temperature was kept at 30° C. The annealed Yb-doped Cs₂AgBiBr₆ powders and YbBr₃ powders were loaded in alumina crucibles. Two powders were deposited simultaneously for 20 minutes. The evaporation rate of YbBr₃ was maintained at 0.05 Å/s with the corresponding temperature of 600° C. The evaporation rate of Yb-doped Cs₂AgBiBr₆ powders vary from 2-4 Å/s, with the corresponding temperature of 400-600° C. The final film thickness calculated from precursors fluxes is about 220 nm.

### Powers and Thin Film Characterizations

X-ray diffraction, scanning electron microscopy, Raman, and PLQY measurements were conducted in the same manner as demonstrated in Example 1 and 2. NIR PL was excited at 360 nm.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

1. A thin film comprising a Yb-doped double perovskite, wherein the double perovskite has the formula M₂AYbₓB₍₁₋ₓ₎X₆;
wherein each occurrence of M independently represents Cs or Rb;
A represents Ag or Cu;
B represents Bi, In, Sb, or Ga;
x has a value between 0.01 and 0.20; and
each X independently represents F, Cl, Br, or I.

2. The thin film of claim 1, wherein the double perovskite has the formula M₂AYbₓB₍₁₋ₓ₎Cl_{(6-y)}Br_{y} wherein y is an integer between 0 and 6.

3. The thin film of claim 2, wherein the double perovskite has the formula Cs₂AgYbₓBi₍₁₋ₓ₎Cl_{(6-y)}Br_{y}.

4. The thin film of claim 1, wherein the double perovskite has the formula Cs₂AgYbₓB₍₁₋ₓ₎Br₆.

5. The thin film of claim 1, wherein the value of x is between 0.05 and 0.10.

6. The thin film of claim 1, wherein the value of x is between 0.06 and 0.09.

7. The thin film of claim 1, wherein a photoluminescence quantum yield of the thin film is at least 45%.

8. A solar cell comprising the thin film of claim 1.

9. The solar cell of claim 8, wherein the solar cell is selected from the group consisting of a silicon solar cell and a copper indium gallium selenide solar cell.

10. A method of formulating a thin film, the method comprising the steps of:
providing a substrate;
providing a source of BX₃;
providing a source of YbX₃;
providing a source of AX;
depositing BX₃, YbX₃, and AX on the substrate, wherein a ratio of molar flux of YbX₃ to molar flux of BX₃ is between 0.01 and 0.15;
providing a source of MX;
depositing MX on the substrate to provide a perovskite mixture; and
annealing the mixture to provide a Yb-doped double perovskite thin film;
wherein M represents Cs or Rb; A represents Ag, Cu, or Au; B represents Bi, In, Sb and Ga; and
each X independently represents F, Cl, Br, or I.

11. The method of claim 10, wherein the ratio of molar flux of YbX₃ to BX₃ is between about 0.06 and 0.09.

12. The method of claim 10, further comprising the step of ball milling at least one of BX₃, YbX₃, AX, and MX to produce a powder.

13. The method of claim 10, wherein BX₃ represents BiX₃; AX represents AgX; MX represents CsX; and each X independently represents Br or Cl.

14. The method of claim 10, wherein BX₃ represents BiBr₃; YbX₃ represents YbBr₃; AX represents AgBr; and MX represents CsBr.

15. The method of claim 14, wherein the BiBr₃ is deposited at an evaporation rate of about 1.5 Å/s.

16. The method of claim 10, wherein the step of depositing MX on the substrate further comprises the step of increasing the temperature of the substrate.

17. The method of claim 10, wherein the temperature of the substrate is increased from about 30° C. to about 83° C. during the deposition of MX.

18. A thin film produced using the method of claim 10.

19. A thin film comprising a Yb-doped double perovskite produced with a method comprising the steps of:
providing a substrate;
providing a source of BX₃;
providing a source of YbX₃;
providing a source of AX;
depositing BX₃, YbX₃, and AX on the substrate, wherein a ratio of molar flux of YbX₃ to molar flux of BX₃ is between 0.01 and 0.15;
providing a source of MX;
depositing MX on the substrate to provide a perovskite mixture; and
annealing the mixture to provide a Yb-doped double perovskite thin film;
wherein M represents Cs or Rb; A represents Ag, Cu, or Au; B represents Bi, In, Sb and Ga; and
each X independently represents F, Cl, Br, or I.

20. The thin film of claim 19, wherein the ratio of molar flux of YbX₃ to BX₃ is between about 0.06 and 0.09.
